(19) United States
(12) Patent Application Publication
(10) Pub. No.: US 2026/0333862 A1
(43) Pub. Date: Oct. 22, 2026

(54) DIFFERENTIATED SHEET HEIGHT IN ADJACENT NANOSHEET STACKS

(71) Applicant: Taiwan Semiconductor Manufacturing Co., Ltd., Hsinchu (TW)

(72) Inventors: Li-Wei Yin, Hsinchu (TW); Kai-Min Chien, New Taipei City (TW); Min-Chia Lee, Hsinchu (TW); I-Hsiang Ma, Hsinchu (TW); Kuo-Chin Liu, Ji-an Township (TW); Yih-Ann Lin, Jhudong Township (TW); Ryan Chia-Jen Chen, Hsinchu (TW)

(21) Appl. No.: 19/724,462

(22) Filed: Jun. 29, 2026

Related U.S. Application Data
(63) Continuation of application No. 18/821,592, filed on Aug. 30, 2024.

(51) Int. Cl. H10D 84/85; H10D 30/01; H10D 30/43; H10D 30/67; H10D 62/10; H10D 64/01; H10D 84/01; H10D 84/03

(52) U.S. Cl. CPC H10D 84/856; H10D 30/014; H10D 30/43; H10D 30/6735; H10D 30/6757; H10D 62/121; H10D 64/017; H10D 84/0167; H10D 84/038

(57) ABSTRACT

A semiconductor device including a substrate including a first device region and a second device region. A first type device is present in the first device region, the first type device including a first stack of nanostructures, and a first gate stack around each first nanostructure of the first stack of nanostructures, wherein said each first nanostructure of the first stack of nanostructures has a first height. A second type device is present in the second device region, the second type device including a second stack of nanostructures, and a second gate stack around each second nanostructure of the second stack of nanostructures, wherein said each second nanostructure of the second stack of nanostructures has a second height. The second height is different than the first height.

### CROSS-REFERENCE TO RELATED APPLICATIONS

This application is a continuation of U.S. application Ser. No. 18/821,592, filed on Aug. 30, 2024, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B 8A, 8B, 9A, 9B, 10A, 10B, 11A, 11B, 11C, 12A, 12B, 12C, 12D, 13A, 13B, 13C, 14A, 14B, 15A, 15B, 16A, 16B, 16C, 16D, 16E, 16F, 16G, 16H, 17A, 17B, 18A, 18B, 18C, 19A, 19B, 19C, 20A, 20B, and 20C are cross-sectional views of intermediate stages in the manufacturing of nano-FETs, in accordance with some embodiments;

FIG. 21A is a plot of activation energy for fluorine to cause a chemical reaction in silicon germanium, in accordance with some embodiments; and

FIG. 21B is a plot of activation energy for hydrogen to cause a chemical reaction in silicon germanium.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments of nanostructure semiconductor devices the nanosheet thickness, e.g., the thickness of the semiconductor layers that provide the channel regions of the device, can define the transistor electrical performance. For example, n-type semiconductor devices, such as n-type field effect transistors (NFETs), benefit from thinner sheet heights. For example, by providing thinner sheet heights in n-type semiconductor devices, such as NFETs, doping effect can be reduced resulting in better channel resistance. N-type field effect transistors (NFETs) and p-type field effect transistors (PFETs) on a same supporting substrate having the same thickness for the semiconductor layers that provide the channel regions of the devices, e.g., nanosheets, do not provide optimized performance for each of the NFET and the PFET. In some embodiments, the methods and structures described herein can offer tunable NFET and PFET performance with differentiated thickness, e.g., differentiated heights, for the semiconductor layers, e.g., nanosheets, providing the channel regions of the devices. In some embodiments, by providing tunable NFET and PFET performance through differentiated thicknesses for the semiconductor layers, e.g., nanosheets, the methods and structures described herein can result in better wafer acceptance testing (WAT) performance. In some embodiments, the methods and structures provided herein can provide tunable differentiated thicknesses for the semiconductor layers of the separate NFET and PFET devices using a one-step etch process that does not rely upon multiple patterning steps to individually etch the stacks for the NFET and PFET devices.

Embodiments are described below in a particular context, a die comprising nano-FETs. Various embodiments may be applied, however, to dies comprising other types of transistors (e.g., fin field effect transistors (FinFETs), planar transistors, or the like) in lieu of or in combination with the nano-FETs.

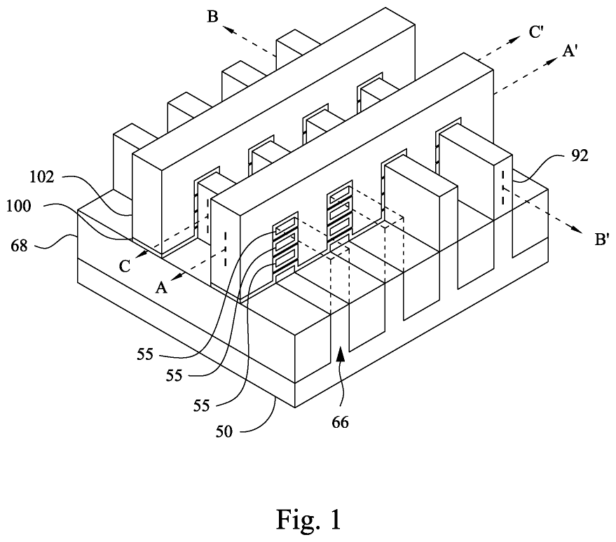

FIG. 1 illustrates an example of nano-FETs (e.g., nanowire FETs, nanosheet FETs (Nano-FETs), or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 are illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET and in a direction of, for example, a current flow between the epitaxial source/drain regions 92 of the nano-FET. Cross-section C-C′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

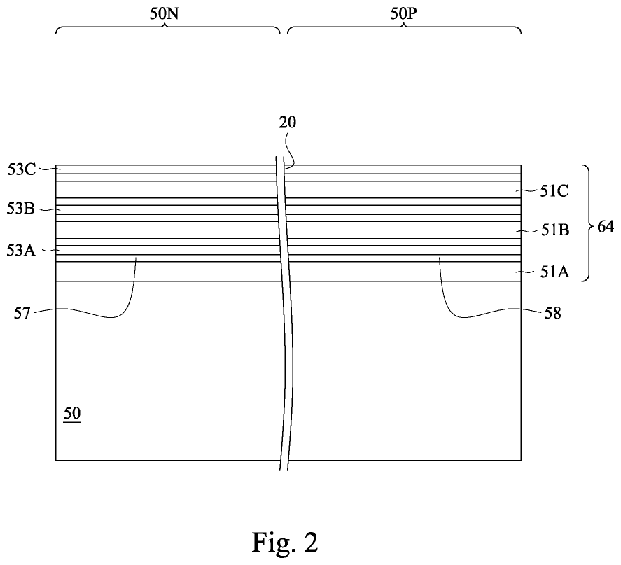

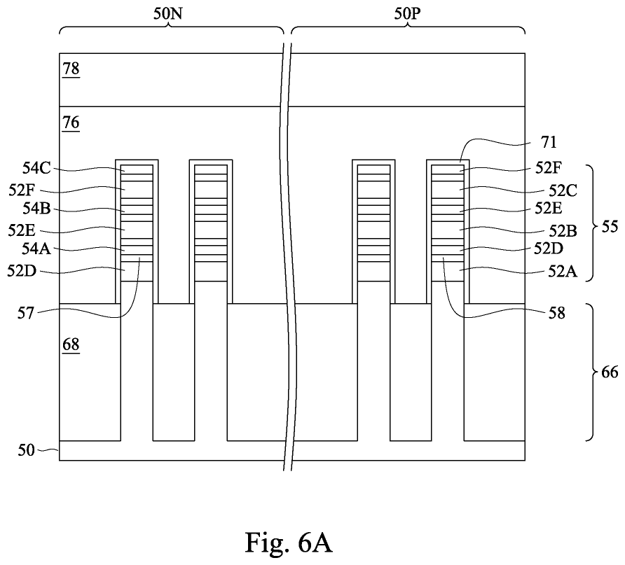

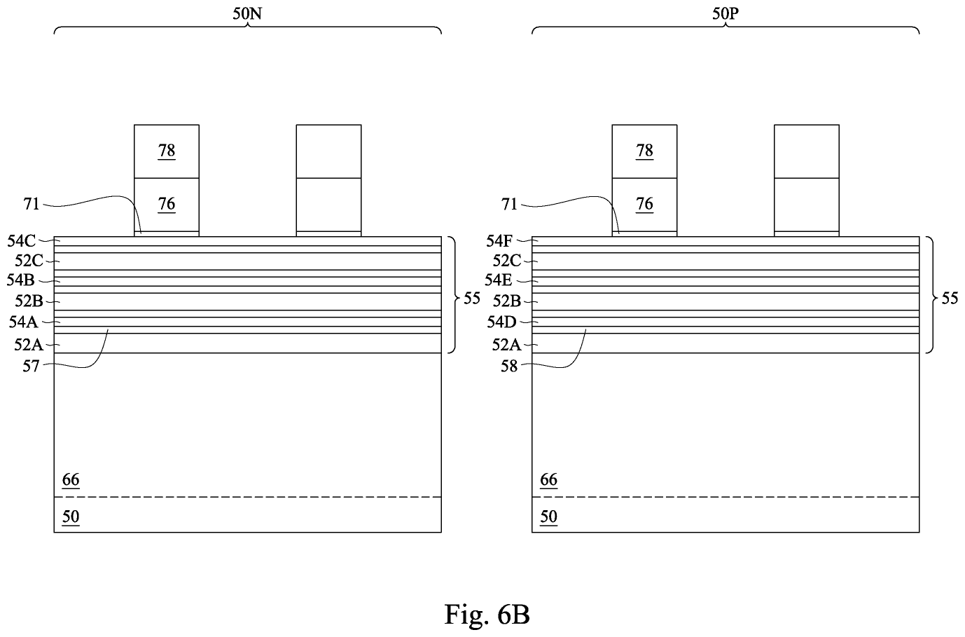

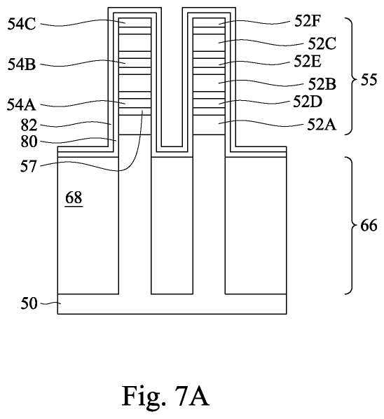

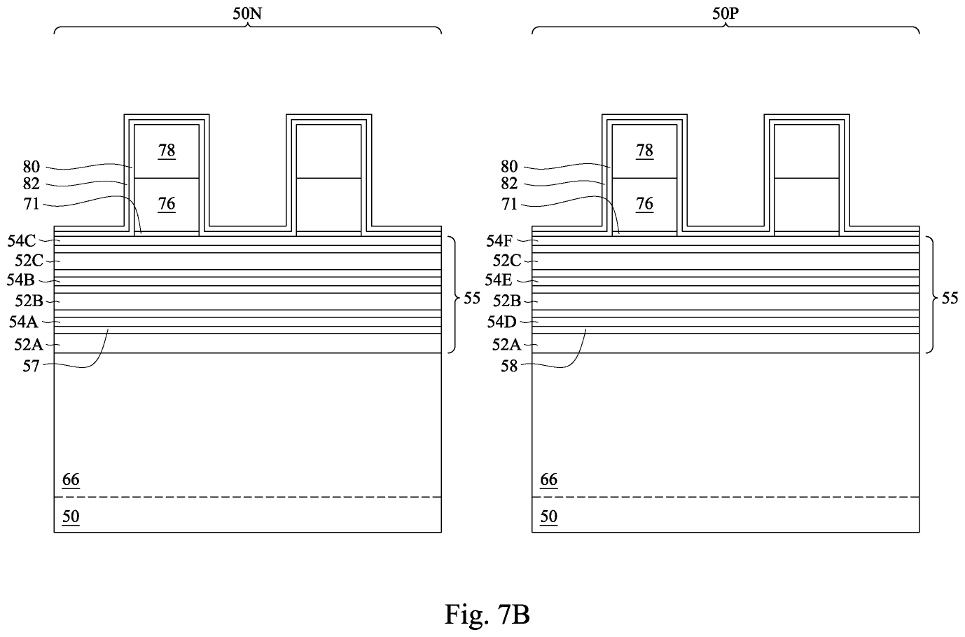

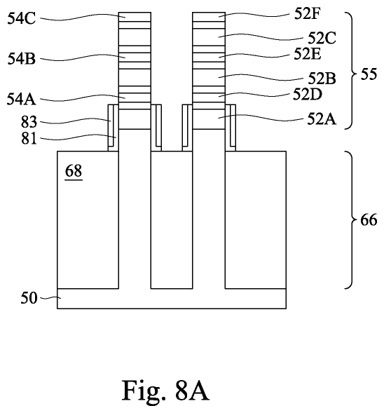

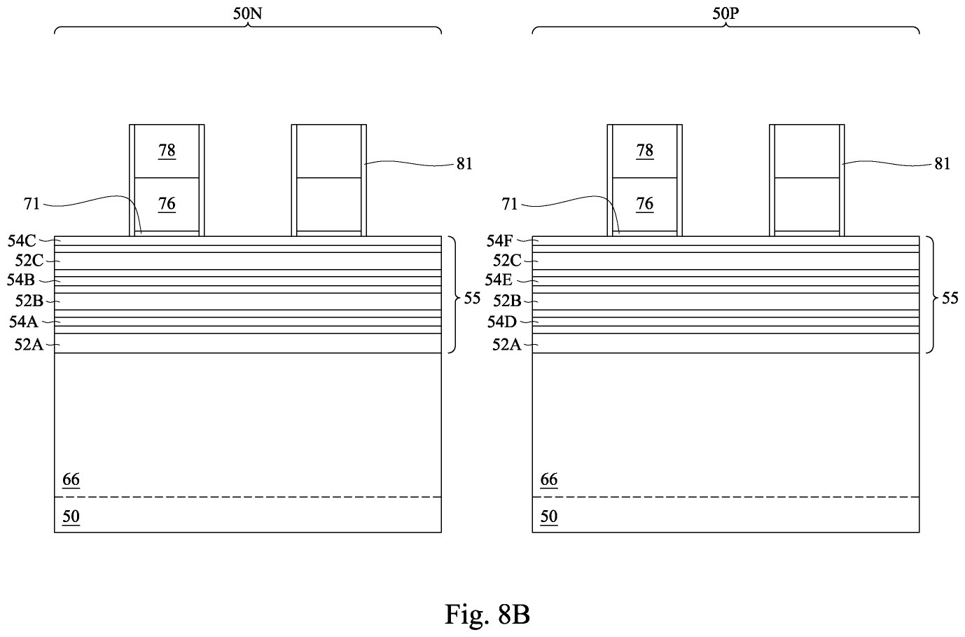

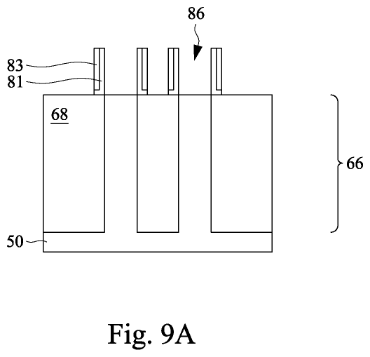

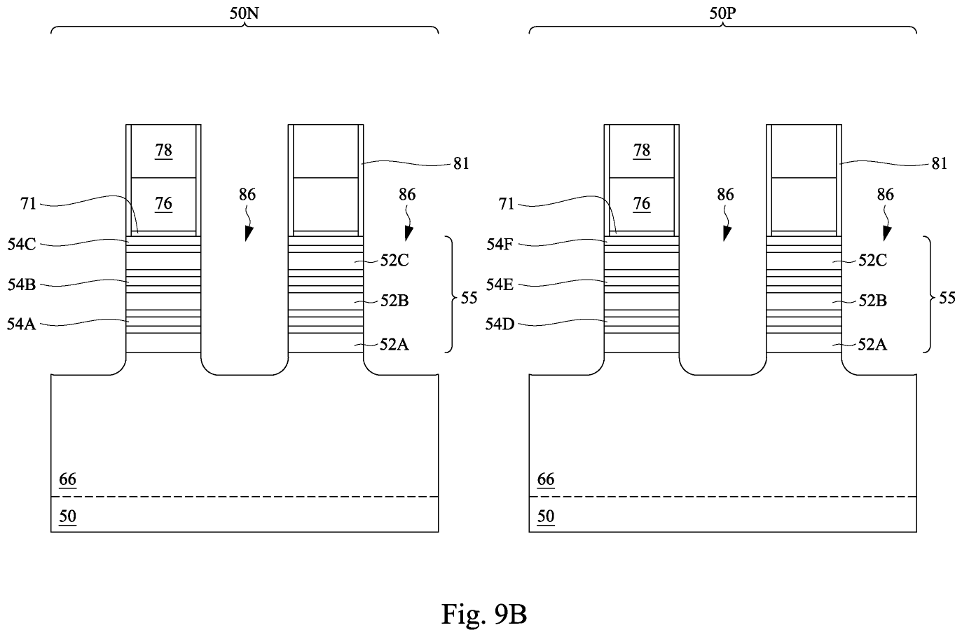

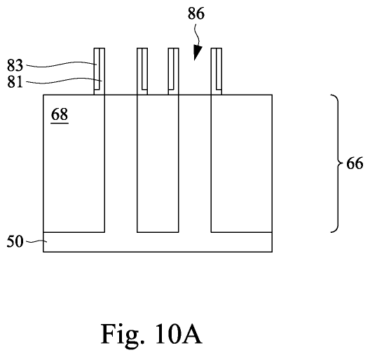

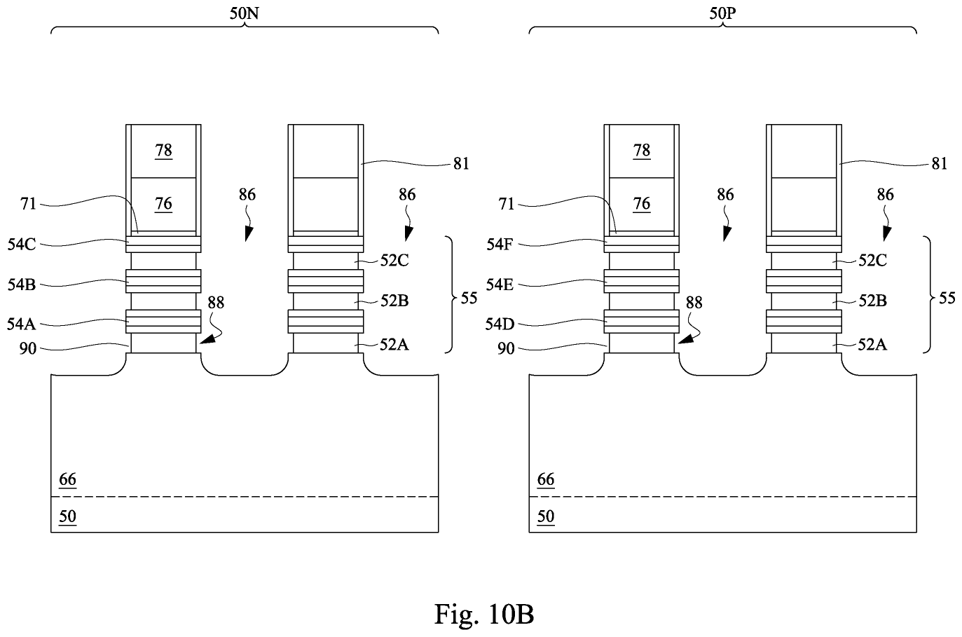

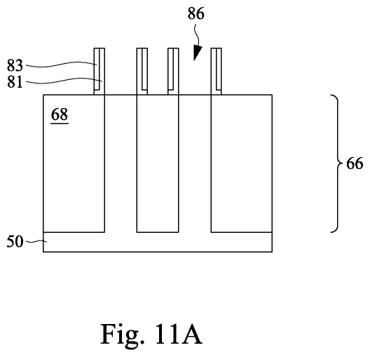

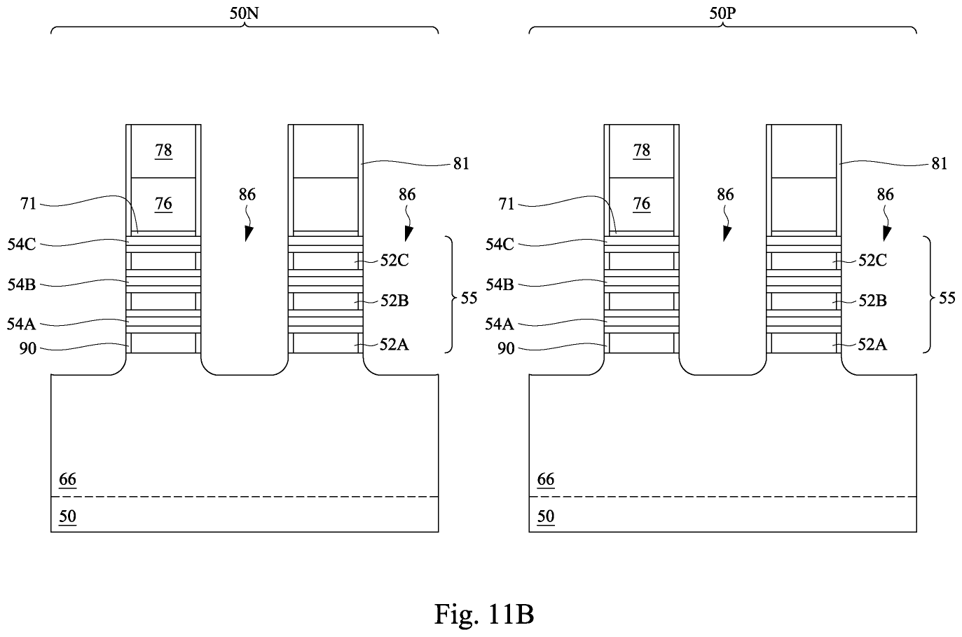

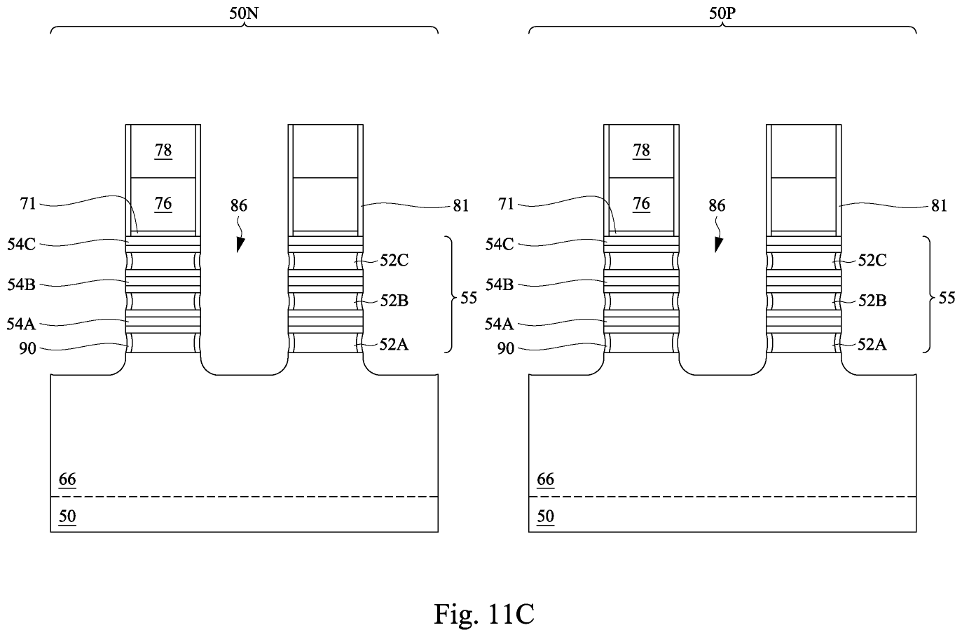

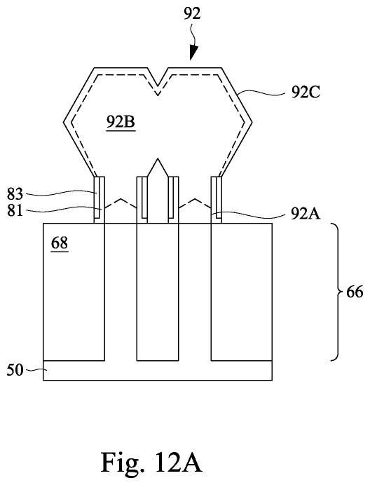

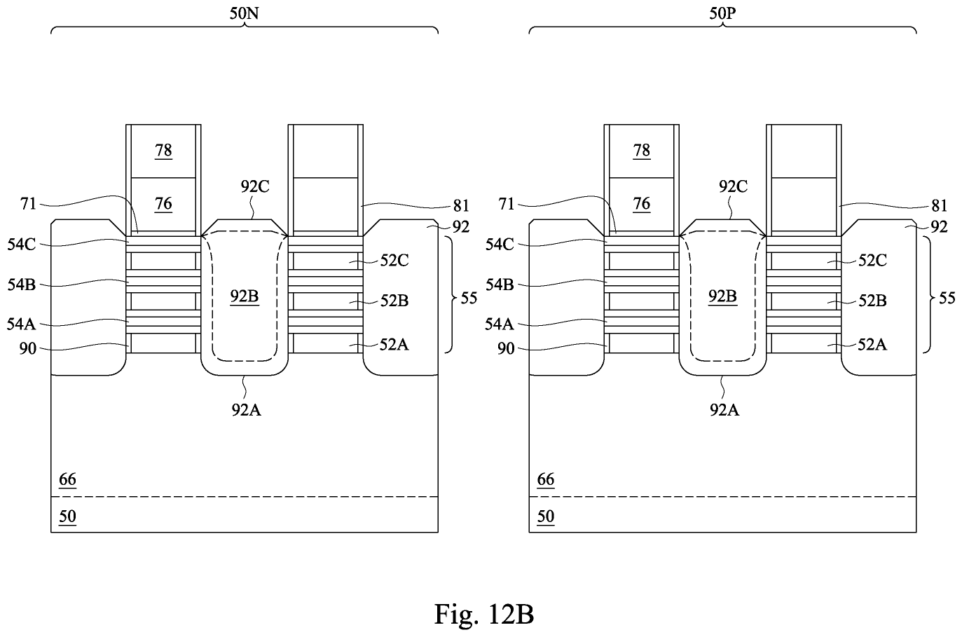

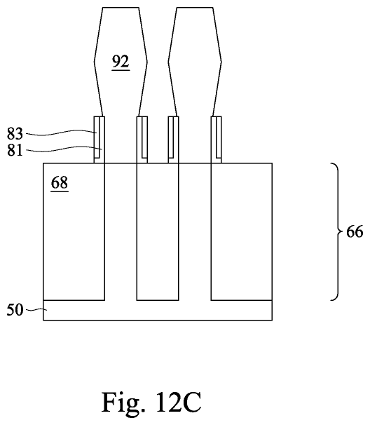

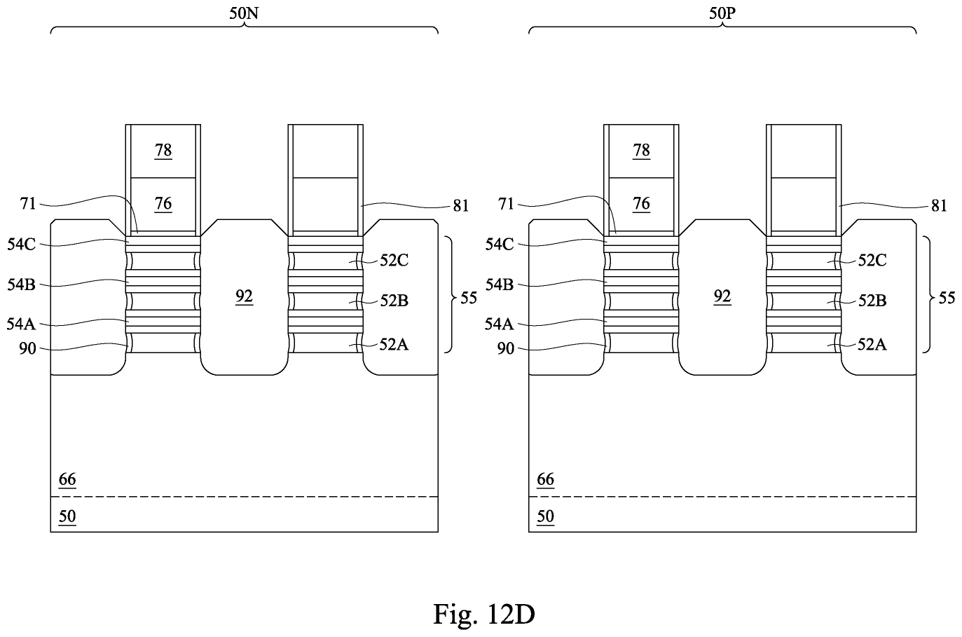

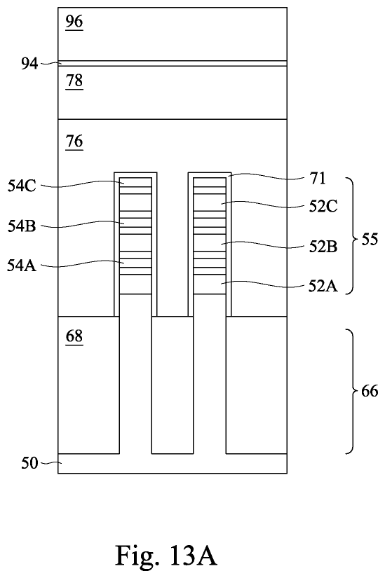

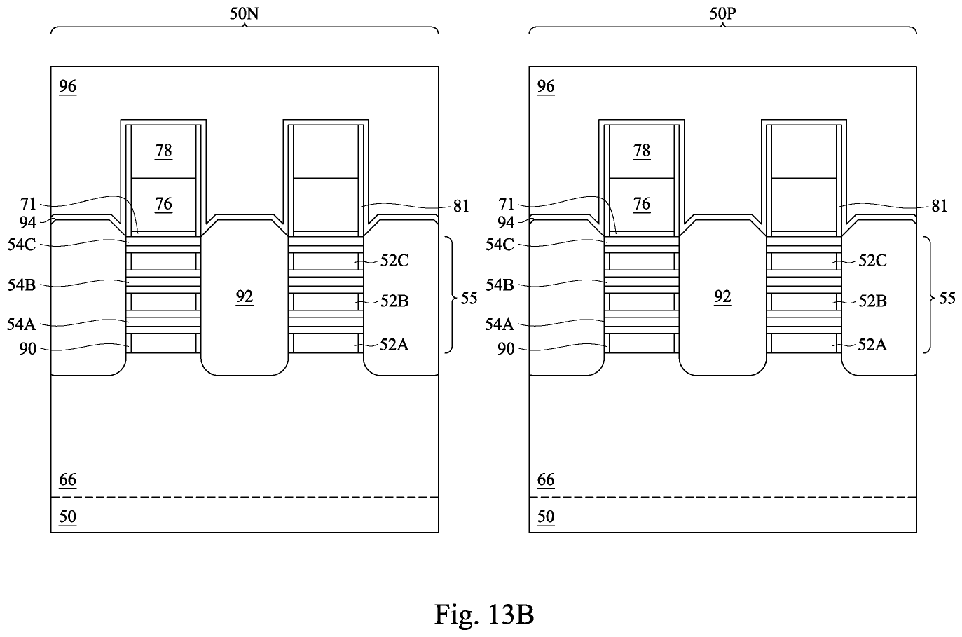

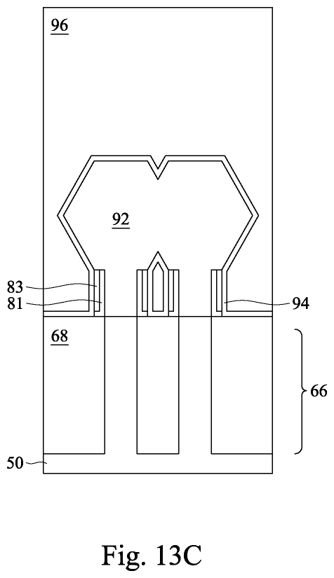

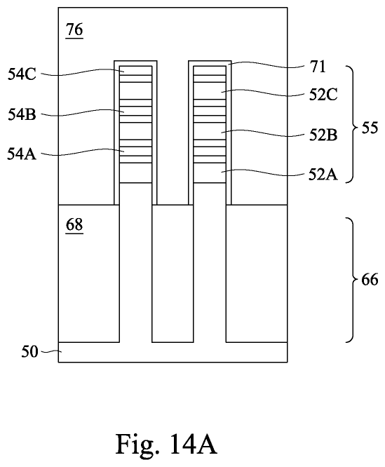

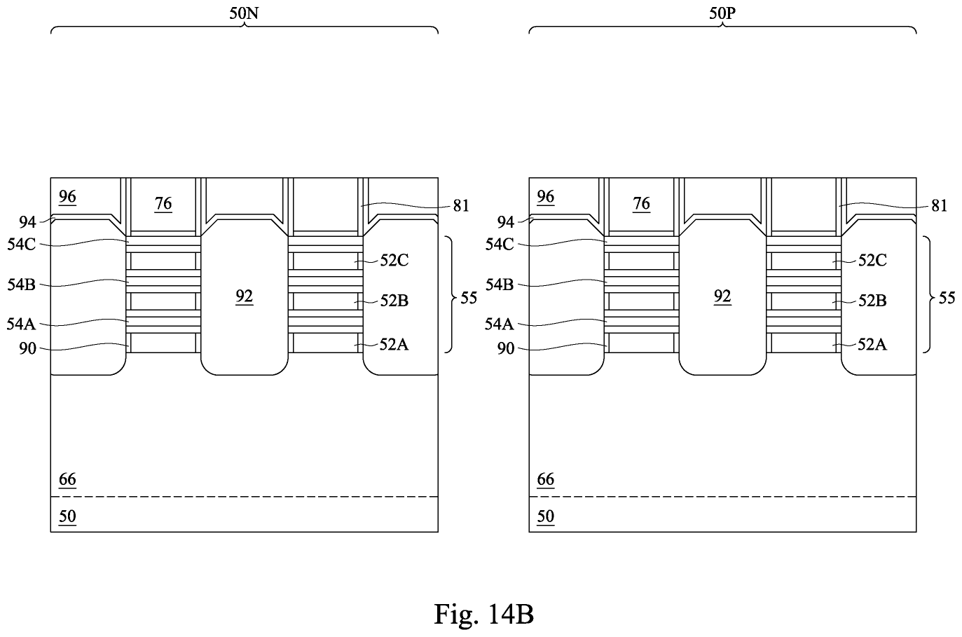

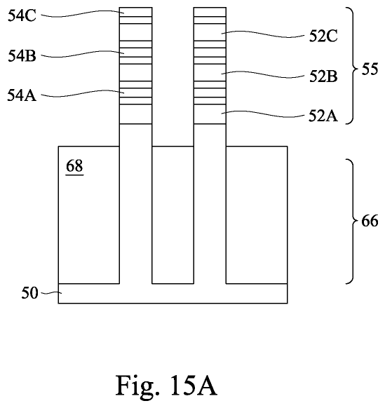

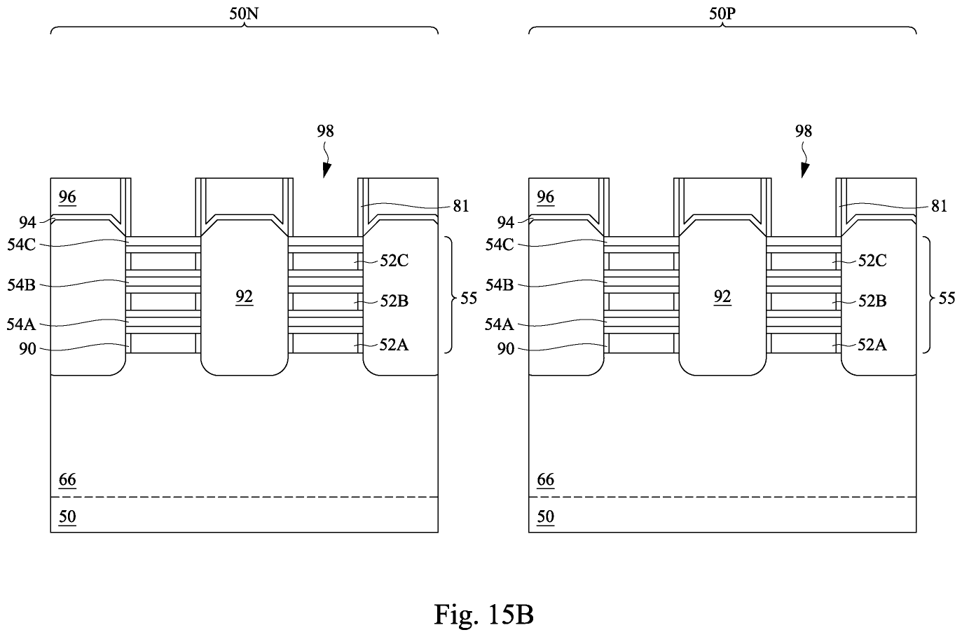

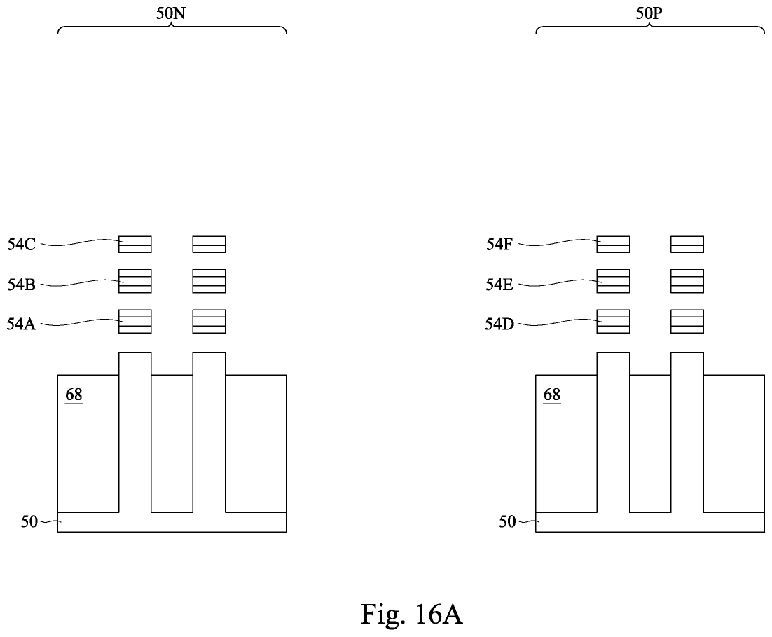

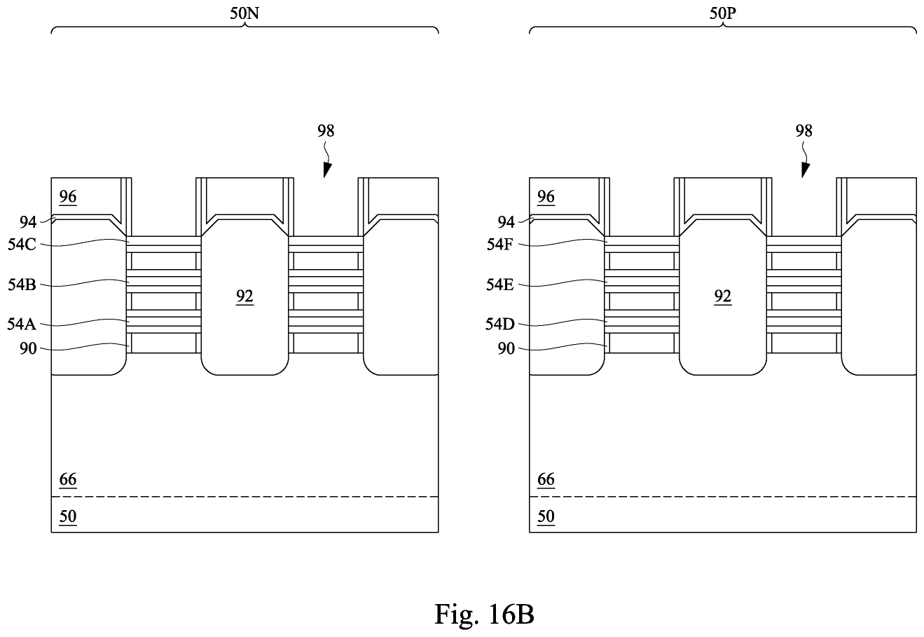

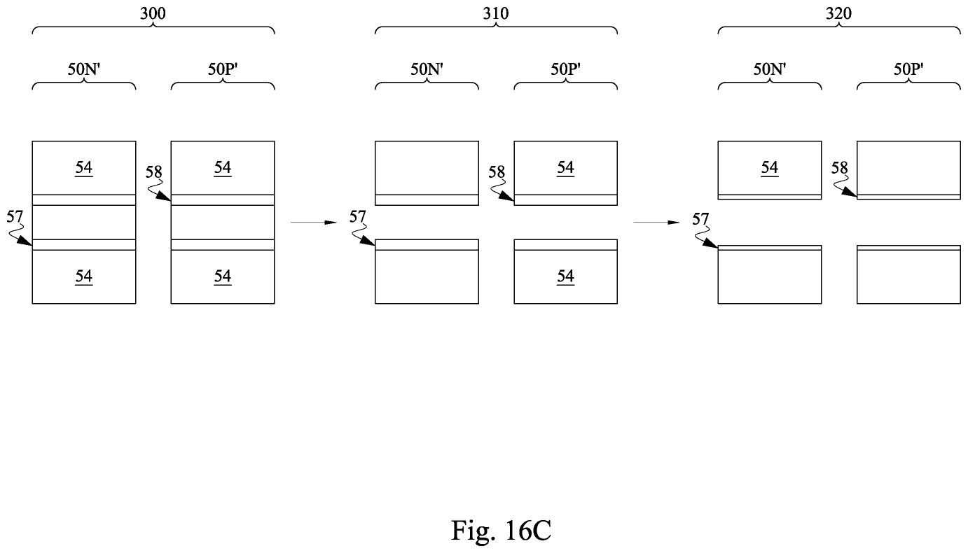

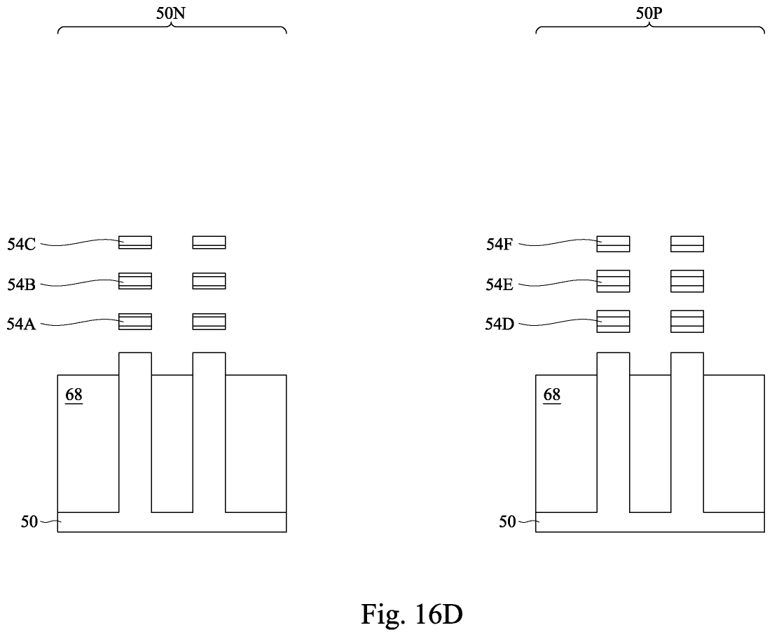

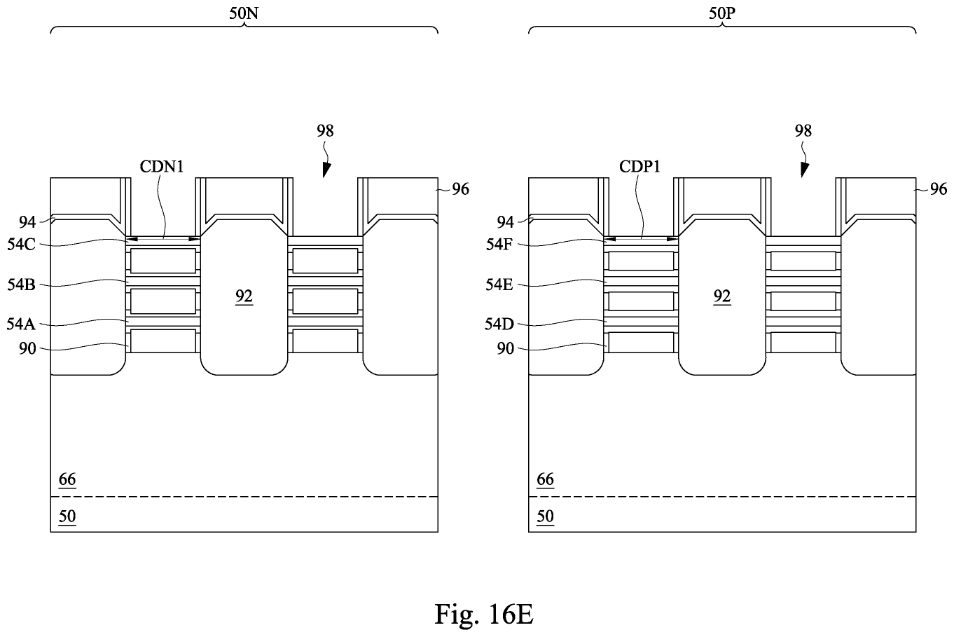

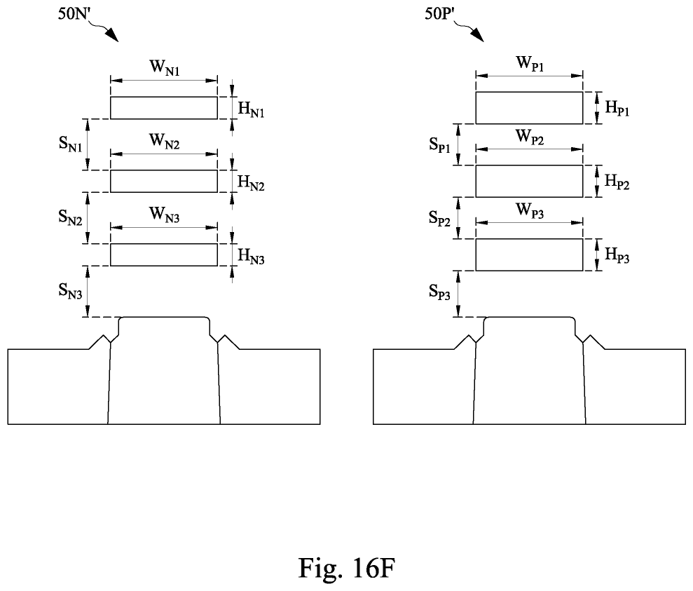

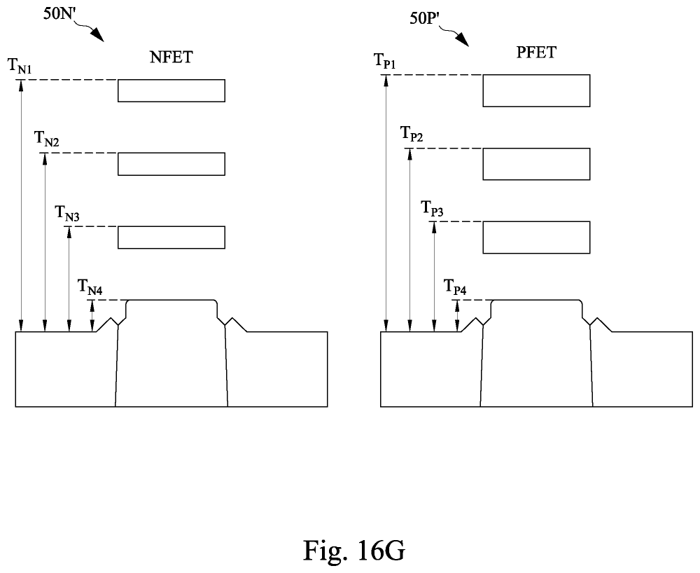

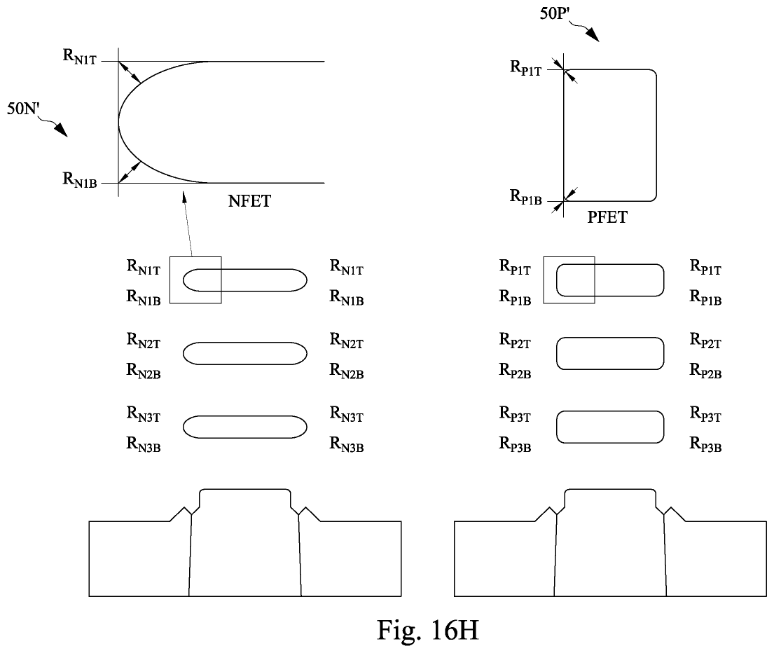

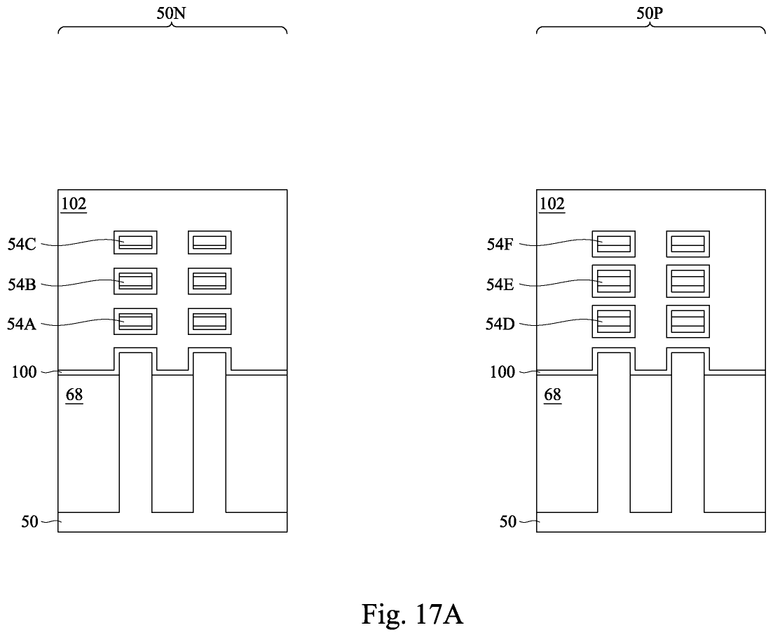

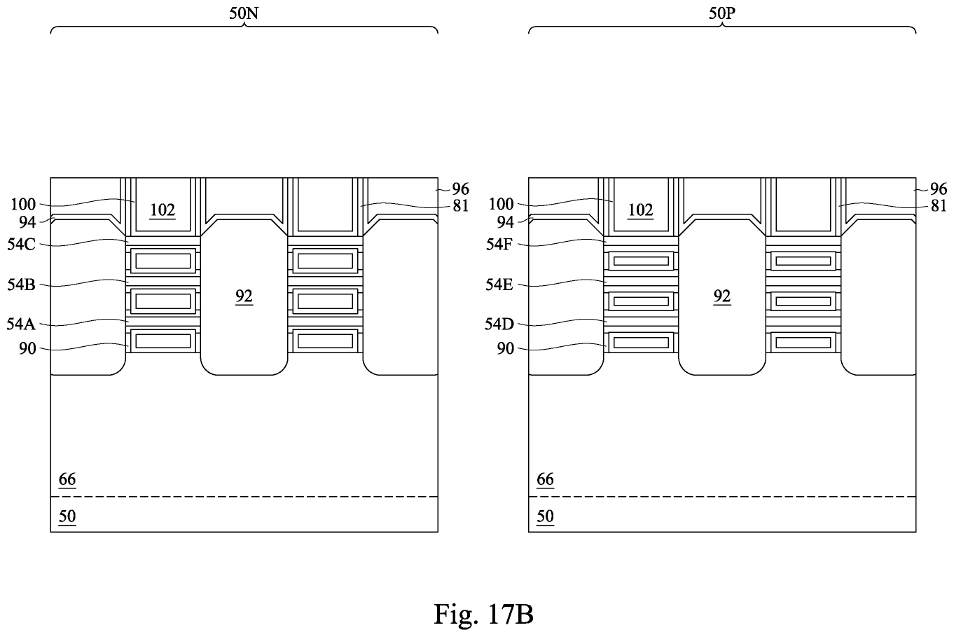

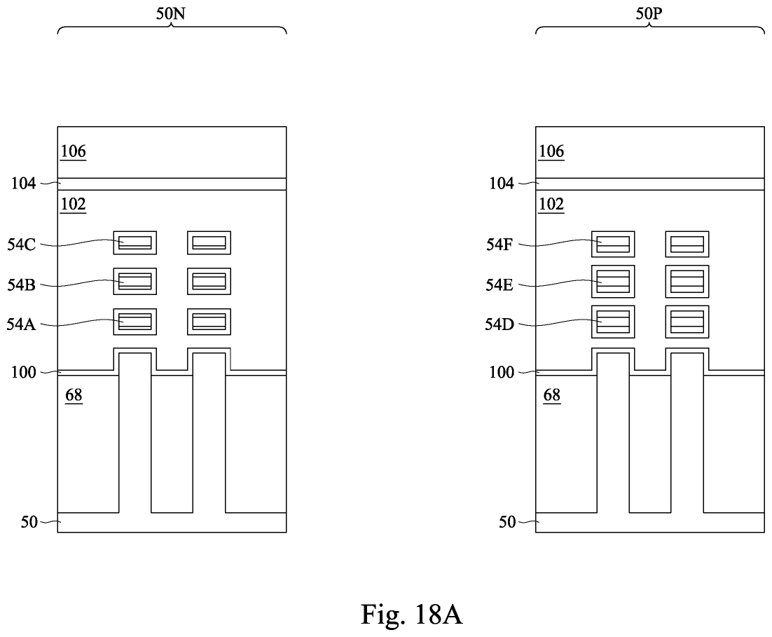

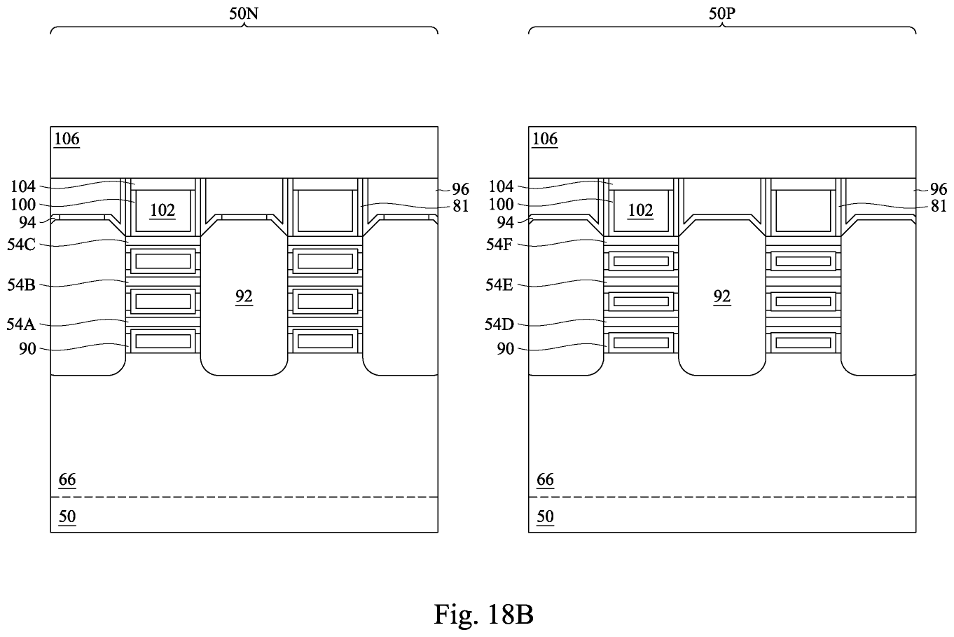

FIGS. 2 through 20C are cross-sectional views of intermediate stages in the manufacturing of nano-FETs, in accordance with some embodiments. FIGS. 2 through 5, 6A, 13A, 14A, 15A, 16A, 16C, 16D, 16F, 16G, 16H, 17A, 18A, 19A, and 20A illustrate reference cross-section A-A′ illustrated in FIG. 1. FIGS. 6B, 7B, 8B, 9B, 10B, 11B, 11C, 12B, 12D, 13B, 14B, 15B, 16B, 16E, 17B, 18B, 19B, 20B, and 21B illustrate reference cross-section B-B′ illustrated in FIG. 1. FIGS. 7A, 8A, 9A, 10A, 11A, 12A, 12C, 13C, 18C, 19C and 20C illustrate reference cross-section C-C′ illustrated in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

In some embodiments, the substrate includes two different conductivity type regions. In some embodiments, the substrate 50 has an n-type region 50N and a p-type region 50P. In some embodiments, the n-type region 50N may provide a first conductivity type region, and the p-type region 50P provides a second conductivity type region. The n-type region 50N can be for forming n-type devices, such as NMOS transistors, e.g., n-type nano-FETs, and the p-type region 50P can be for forming p-type devices, such as PMOS transistors, e.g., p-type nano-FETs. The n-type region 50N may be physically separated from the p-type region 50P (as illustrated by divider 20), and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be provided.

Further in FIG. 2, a multi-layer stack 64 is formed over the substrate 50. The multi-layer stack 64 includes alternating layers of first semiconductor layers 51A-C (collectively referred to as first semiconductor layers 51) and second semiconductor layers 53A-C (collectively referred to as second semiconductor layers 53). For purposes of illustration and as discussed in greater detail below, the first semiconductor layers 51 will be removed and the second semiconductor layers 53 will be patterned to form channel regions of the nano-FETs in the n-type region 50N and the p-type region 50P. However, in some other embodiments, the second semiconductor layers 53 will be removed and the first semiconductor layers 51 will be patterned to form channel regions of the nano-FETs in the n-type region 50N and the p-type region 50P. In such embodiments, the channel regions in both the n-type region 50N and the p-type region 50P may have a same material composition (e.g., silicon, or the another semiconductor material) and be formed simultaneously.

Referring to FIG. 2, the multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like. In various embodiments, the first semiconductor layers 51 may be formed of a first semiconductor material suitable for p-type nano-FETs, such as silicon germanium, or the like, and the second semiconductor layers 53 may be formed of a second semiconductor material suitable for n-type nano-FETs, such as silicon, silicon carbon, or the like.

The first semiconductor materials and the second semiconductor materials may be materials having a high-etch selectivity to one another. As such, the first semiconductor layers 51 may be removed without significantly removing the second semiconductor layers 53. Similarly, the second semiconductor layers 53 of the second semiconductor material may be removed without significantly removing the first semiconductor layers 51 of the first semiconductor material.

In some embodiments, the first semiconductor layers 51 may be composed of germanium containing material, such as silicon germanium (SiGe). In one example, the germanium content of the silicon germanium (SiGe) composition of the first semiconductor layers 51 may range from 15% to 40%. The second semiconductor layers 53 may be composed of a silicon containing material, such as silicon (Si).

In some embodiments, a mixed composition interface layer 57, 58 may be formed between the first semiconductor layers 51 and the second semiconductor layers 51, 53. In some embodiments, the epitaxial deposition process that is employed for forming the first and second semiconductor layers 51, 53 also forms the mixed composition interface layers 57, 58. More particularly, as the forming gasses are switched in the epitaxial deposition forming sequence for forming the alternating first and second semiconductor layers 51, 53, an epitaxially formed interface layer, e.g., the first and second mixed composition interface layers 57, 58, is produced by mixed forming gasses at the interface of the first and second semiconductor layers 51, 53. In some embodiments, the mixed composition interface layer 57, 58 includes elements from the first semiconductor layers 51 and the second semiconductor layers 53. In some examples, the mixed composition interface layer 57, 58 is a silicon containing layer including germanium from the first semiconductor layers 51.

As will be further described below with reference to FIGS. 11A-12, the mixed composition interface layers 57, 58 may be doped to modify their etch rate. More particularly, the dopant may be introduced in the source/drain regions 92, and then diffused into the first and second mixed composition interface layers 57, 58 by thermal diffusions, e.g., during annealing process steps. For example, a first mixed composition interface layer 57 may be present within the n-type region 50N and a second mixed composition interface layer 58 may be present within the p-type region 50P. The etch processes in combination with the composition and dopants in the first mixed composition interface layer 57 may be selective to increase the etch rate of the first mixed composition interface layer 57 in the n-type region 50N relative to the second mixed composition interface layer 58 that is present within the p-type region 50P. For example, the portions of the mixed composition interface layer, e.g., the first mixed composition interface layer 57, within the n-type region 50N may be doped with an n-type dopant, and the portions of the mixed composition interface layer, e.g., the second mixed composition interface layer 58, within the p-type region 50P may be doped with a p-type dopant. In one example, the n-type dopant that is present in the mixed composition interface layer within the n-type region 50N may be selected from phosphorus, arsenic, antimony and combinations thereof. In one example, the p-type dopant that is present in the mixed composition interface layer within the p-type region 50P may be selected from boron, boron fluoride, indium and combinations thereof. The n-type and p-type dopants may be diffused into the mixed composition interface layer from the first semiconductor layers 51.

In some other embodiments, the portion of the first semiconductor layer 51 that is present in the n-type region may be doped with an n-type dopant that diffuses to the interface with the second semiconductor layers 53 to provide an n-type doped first mixed composition interface layer 57 within the n-type region 50N. In some examples, the first mixed composition interface layer that is formed in the n-type region 50N is a silicon containing layer including from 0.1% to 5% germanium (Ge) and from 0.01 to 1% phosphorus (P).

In some embodiments, the portion of the first semiconductor layer 51 that is present in the p-type region 50P may be doped with a p-type dopant that diffuses to the interface with the second semiconductor layers 53 to provide a p-type doped second mixed composition interface layer 58 within the p-type region 50P. In some examples, the second mixed composition interface layer 58 that is formed in the p-type region 50P is a silicon containing layer including from 0.01% to 5% germanium (Ge) and from 0.01% to 1% boron (B).

The n-type and p-type dopants may be introduced to the first semiconductor layers 51 by ion implantation, in situ doping or a combination thereof. The separate processing applied to the n-type region and the p-type region may be achieved using a photoresist mask or other masks (not separately illustrated). The photoresist mask can be formed by using a spin-on technique and can be patterned using acceptable photolithography techniques. For example, to introduce the n-type dopant to the first semiconductor layers 51, a first mask may be applied to the p-type region 50P, and the stack of first and second semiconductor layers 51, 53 may be formed in the n-type region 50N, in which during deposition of the first semiconductor layers 51, the n-type dopant can be introduced using in situ doping. Following the formation of the stack of first and second semiconductor layers in the n-type region 50N, the first mask may be removed, e.g., by oxygen ashing. Thereafter, a second mask may be formed over the n-type region 50N, and the p-type region 50P may be processed to provide first semiconductor layers 51 having p-type dopant. For example, after the second mask is applied to the n-type region, the stack of first and second semiconductor layers 51, 53 may be formed in the p-type region 50P, in which during deposition of the first semiconductor layers 51, the p-type dopant can be introduced using in situ doping. In some embodiments, an ion implantation process may be employed to introduce the n-type or p-type dopants instead of using in situ doping.

Although the mixed composition interface layer can be formed by diffusion of elements from the first semiconductor layer 51 and the second semiconductor layer 53 at the interface there between, embodiments have been contemplated in which the first and second mixed composition interface layer 57, 58 may be formed using a separate deposition step from the deposition steps that form the first and second semiconductor layers 51, 53.

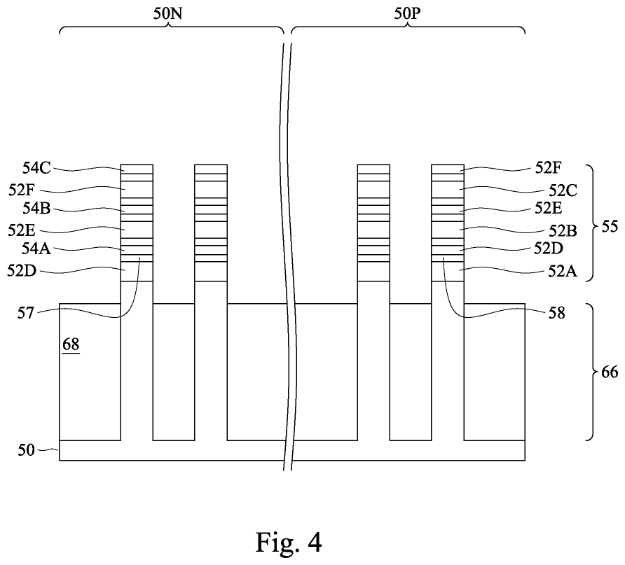

Referring now to FIG. 4, fins 66 are formed in the substrate 50 and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-F (collectively referred to as the sacrificial nanostructures 52) from the first semiconductor layers 51 and define second nanostructures 54A-F from the second semiconductor layers 53. Between the first nanostructures 52A-F and the second nanostructures 54A-F are the first and second mixed composition interface layers 57, 58. The second nanostructures 54A, 54B and 54C provide the nanostructures of the first stack in the first conductivity type region (n-type region 50N). The second nanostructures 54D, 54E, and 54F provide the nanostructures of the second stack in the second conductivity region (p-type region 50P). The first mixed composition interface layers 57 are present in the N-type region 50N, and the second composition interface layers 58 are present in the P-type region 50P. The first nanostructures 52 and the second nanostructures 54 may further be collectively referred to as nanostructures 55.

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66.

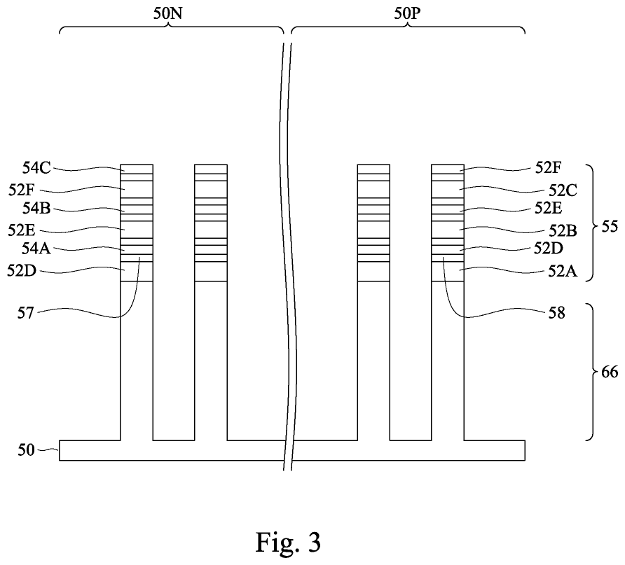

FIG. 3 illustrates the fins 66 in the n-type region 50N and the p-type region 50P as having substantially equal widths for illustrative purposes. In some embodiments, widths of the fins 66 in the n-type region 50N may be greater or thinner than the fins 66 in the p-type region 50P. Further, while each of the fins 66 and the nanostructures 55 are illustrated as having a consistent width throughout, in other embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width.

In some embodiments, a first mixed composition interface layer 57 may be present at the interface for the stacked layers for the first nanostructures 52 and the second nanostructures 54 in the first stacks that are present in the n-type region 50A; and a second mixed composition interface layer 58 may be present at an interface for the stacked layers for the first nanostructures 52 and the second nanostructures 54 of the p-type region 50B. The first mixed composition interface layer 57 and the second mixed composition interface layer 58 may each contain a majority amount of silicon (Si) and a minority amount of germanium (Ge) from the first nanostructures 52. For example, the germanium content in each of the first and second mixed composition interface layers 57, 58 may be 5% or less. The first and second mixed composition interface layers 57, 58 may be formed by intermixing of the deposition elements during the epitaxial deposition sequence for forming the multi-layered stack 64 depicted in FIG. 2. In some embodiments, intermixing of the different compositions form the first nanostructures 52 and the second nanostructures 54 to provide the first and second mixed composition interface layers 57, 58 can be provided by thermal diffusion during annealing steps.

Further, the first mixed composition interface layer 57 can include up to 1% of an n-type dopant, such as phosphorus (P). The n-type dopant can be introduced to the first mixed composition interface layer 57 by diffusion, e.g., thermal diffusion, from the later formed source/drain regions 92, as described above with reference to FIGS. 11A-11C. However, in some other embodiments, the n-type dopant can be introduced to the first mixed composition interface layer 57 by diffusion, e.g., thermal diffusion, from the first nanostructures 52D, 52E, 52F in the n-type region 50N. In one example, the n-type dopant may be provided by phosphorus (P) dopant present in the first mixed composition interface layer 56 in amounts ranging from 0.01% to 1%.

Further, the second mixed composition interface layer 58 can include up to 1% of a p-type dopant, such as boron (B). The p-type dopant can be introduced to the second mixed composition interface layer 58 by diffusion, e.g., thermal diffusion, from the first nanostructures 52A, 52B, 52C in the p-type region 50P. In one example, the n-type dopant may be provided by boron (B) dopant present in the second mixed composition interface layer 58 in amounts ranging from 0.01% to 1%.

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, in some embodiments, a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 in the n-type region 50N and the p-type region 50P protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

The first semiconductor layers 51 (and resulting nanostructures 52) and the second semiconductor layers 53 (and resulting nanostructures 54) are illustrated and discussed herein as comprising the same materials in the p-type region 50P and the n-type region 50N for illustrative purposes only. As such, in some embodiments one or both of the first semiconductor layers 51 and the second semiconductor layers 53 may be different materials or formed in a different order in the p-type region 50P and the n-type region 50N. However, the materials selected for the first and second semiconductor layers 53 are to have etch selectivity parameters that are being used by the process flow described herein.

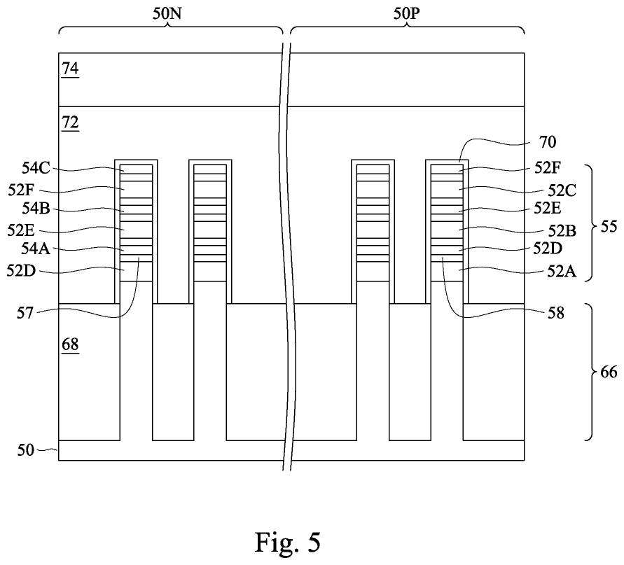

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a CMP. The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In this example, a single dummy gate layer 72 and a single mask layer 74 are formed across the n-type region 50N and the p-type region 50P. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 18C illustrate various additional steps in the manufacturing of embodiment devices. FIGS. 7A, 8A, 9A, 10A, 11A, 12A, 12C, 13A, 13C, 14A, 15A, and 18C illustrate features in either the n-type regions 50N or the p-type regions 50P. In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55, and the masks 78; and sidewalls of the dummy gates 76 and the dummy gate dielectric 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After the first spacer layer 80 is formed and prior to forming the second spacer layer 82, implants for lightly doped source/drain (LDD) regions (not separately illustrated) may be performed. In embodiments with different device types, similar to the implants discussed above in FIG. 4, a mask, such as a photoresist, may be formed over the n-type region 50N, while exposing the p-type region 50P, and appropriate type (e.g., p-type) impurities may be implanted into the exposed fins 66 and nanostructures 55 in the p-type region 50P. The mask may then be removed. Subsequently, a mask, such as a photoresist, may be formed over the p-type region 50P while exposing the n-type region 50N, and appropriate type impurities (e.g., n-type) may be implanted into the exposed fins 66 and nanostructures 55 in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 1×1015 atoms/cm3 to about 1×1019 atoms/cm3. An anneal may be used to repair implant damage and to activate the implanted impurities.

It is noted that the anneal process described above for repairing the implant damage may also cause elements from the first nanostructures 52 and the second nanostructures 54 to diffuse to the interface between the first nanostructures 52 and the second nanostructures 54 forming the first and second mixed composition interface layer 57, 58, as depicted in FIG. 16C.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etching process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 acts as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy dielectric layers 60. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps.

In FIGS. 9A and 9B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68; or the like. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88 in the n-type region 50N, and form sidewall recesses 88 in the p-type region 50P. Although sidewalls of the first nanostructures 52 and the second nanostructures 54 in sidewall recesses 88 are illustrated as being straight in FIG. 10B, the sidewalls may be concave or convex. The sidewalls may be etched using isotropic etching processes, such as wet etching or the like. In an embodiment in which the first nanostructures 52 include, e.g., SiGe, and the second nanostructures 54 include, e.g., Si or SiC, a dry etch process with tetramethylammonium hydroxide (TMAH), ammonium hydroxide (NH4OH), or the like may be used to etch sidewalls of the first nanostructures 52 in the n-type region 50N and the p-type region 50P.

In FIGS. 11A-11C, first inner spacers 90 are formed in the sidewall recess 88. The first inner spacers 90 may be formed by depositing an inner spacer layer (not separately illustrated) over the structures illustrated in FIGS. 10A and 10B. The first inner spacers 90 act as isolation features between subsequently formed source/drain regions and a gate structure. As will be discussed in greater detail below, source/drain regions will be formed in the first recesses 86, while the first nanostructures 52 in the n-type region 50N and the second nanostructures 54 in the p-type region 50P will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the n-type region 50N and flush with the sidewalls of the first nanostructures 52 in the p-type region 50P, the outer sidewalls of the first inner spacers 90 may extend beyond or be recessed from sidewalls of the second nanostructures 54 and/or the first nanostructures 52, respectively.

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers 90 are recessed from sidewalls of the second nanostructures 54 in the n-type region 50N. Also illustrated are embodiments in which sidewalls of the second nanostructures 54 are concave, outer sidewalls of the first inner spacers 90 are concave, and the first inner spacers 90 are recessed from sidewalls of the first nanostructures 52 in the p-type region 50P. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A-12C) by subsequent etching processes, such as etching processes used to form gate structures.

In FIGS. 12A-12C, epitaxial source/drain regions 92 are formed in the first recesses 86. In some embodiments, the source/drain regions 92 may exert stress on the second nanostructures 54 in the n-type region 50N and the p-type region 50P, thereby improving performance. As illustrated in FIG. 12B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 in the n-type region 50N, e.g., the NMOS region, may be formed by masking the p-type region 50P, e.g., the PMOS region. Then, the epitaxial source/drain regions 92 are epitaxially grown in the first recesses 86 in the n-type region 50N. The epitaxial source/drain regions 92 may include any acceptable material appropriate for n-type nano-FETs.

In some examples, if the second nanostructures 54 are silicon, the epitaxial source/drain regions 92 may include materials exerting a tensile strain on the second nanostructures 54, such as silicon, silicon carbide, phosphorous doped silicon carbide, silicon phosphide, or the like. The epitaxial source/drain regions 92 may have surfaces raised from respective upper surfaces of the nanostructures 55 and may have facets.

The epitaxial source/drain regions 92 in the p-type region 50P, e.g., the PMOS region, may be formed by masking the n-type region 50N, e.g., the NMOS region. Then, the epitaxial source/drain regions 92 are epitaxially grown in the first recesses 86 in the p-type region 50P. The epitaxial source/drain regions 92 may include any acceptable material appropriate for p-type nano-FETs. For example, if the second nanostructures 54 are silicon, the epitaxial source/drain regions 92 may comprise materials exerting a compressive strain on the first nanostructures 52, such as silicon-germanium, boron doped silicon-germanium, germanium, germanium tin, or the like. The epitaxial source/drain regions 92 may also have surfaces raised from respective surfaces of the multi-layer stack 56 and may have facets.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal. The source/drain regions may have an impurity concentration of between about 1×1019 atoms/cm3 and about 1×1021 atoms/cm3. The n-type and/or p-type impurities for source/drain regions may be any of the impurities previously discussed. In some embodiments, the epitaxial source/drain regions 92 may be in situ doped during growth.

In some embodiments, the n-type dopant of the epitaxial source/drain regions 92 in the n-type region 50N are diffused to the first mixed composition interface layers 57 that are present within the stacks of nanostructures 55 between the first nanostructures 51 and the second nanostructures 53. For example, phosphors may be an n-type dopant that can be diffused from the epitaxial source/drain regions 92 to the first mixed composition interface layers 57 that are present in the n-type region 50N, in which the n-type dopants can increase the etch rate of the first mixed composition interface layers 57 when compared to the etch rate of the second mixed composition interface layers 57 that include p-type dopant. Diffusion of the n-type dopant may be by thermal diffusion, which can result from any anneal step of the process flow.

In some embodiments, the p-type dopant of the epitaxial source/drain regions 92 in the p-type region 50P are diffused to the second mixed composition interface layers 58 that are present within the stacks of nanostructures 55 between the first nanostructures 51 and the second nanostructures 53. For example, boron may be a p-type dopant that can be diffused from the epitaxial source/drain regions 92 to the second mixed composition interface layers 58 that are present in the p-type region 50p. When compared to the phosphorus (n-type) doped first intermixed composition interface layer 57 in the n-type region 50N, the boron for the n-type dopant in the second intermixed composition interface layer 58 etches at a slower etch rate. Diffusion of the p-type dopant may be by thermal diffusion, which can result from any anneal step of the process flow. The dopant from the source/drain regions 92 also diffuses into the first and second nanostructures 52, 54.

The difference in etch rates for the first and second intermixed composition interface layers 57, 58 allow for both stacks of nanostructures 55 to be simultaneously processed, while providing different thicknesses for the nanostructures that ultimately provide the channel regions for the device in the n-type region 50N and the p-type region 50P.

As a result of the epitaxy processes used to form the epitaxial source/drain regions 92 in the n-type region 50N and the p-type region 50P, upper surfaces of the epitaxial source/drain regions 92 have facets which expand laterally outward beyond sidewalls of the nanostructures 55. In some embodiments, these facets cause adjacent epitaxial source/drain regions 92 of a same nano-FET to merge as illustrated by FIG. 12A. In other embodiments, adjacent epitaxial source/drain regions 92 remain separated after the epitaxy process is completed as illustrated by FIG. 12C. In the embodiments illustrated in FIGS. 12A and 12C, the first spacers 81 may be formed to a top surface of the STI regions 68 thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 12D illustrates an embodiment in which sidewalls of the first nanostructures 52 in the n-type region 50N and sidewalls of the second nanostructures 54 in the p-type region 50P are concave, outer sidewalls of the first inner spacers 90 are concave, and the first inner spacers 90 are recessed from sidewalls of the second nanostructures 54. As illustrated in FIG. 12D, the epitaxial source/drain regions 92 may be formed in contact with the first inner spacers 90 and may extend past sidewalls of the second nanostructures 54 in the n-type region 50N and past sidewalls of the second nanostructures 54 in the p-type region 50P.

In FIGS. 13A-13C, a first interlayer dielectric (ILD) 96 is deposited over the structure illustrated in FIGS. 6A, 12B, and 12A (the processes of FIGS. 7A-12D do not alter the cross-section illustrated in FIG. 6A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as, silicon nitride, silicon oxide, silicon oxynitride, or the like, having a different etch rate than the material of the overlying first ILD 96.

In FIGS. 14A-14C, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with top surface of the masks 78 and the first spacers 81.

In FIGS. 15A and 15B, the dummy gates 76, and the masks 78 if present, are removed in one or more etching steps, so that second recesses 98 are formed. Portions of the dummy dielectric layers 60 in the second recesses 98 are also be removed. In some embodiments, the dummy gates 76 and the dummy dielectric layers 60 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55 which act as the channel regions are disposed between neighboring pairs of the epitaxial source/drain regions 92. During the removal, the dummy dielectric layers 60 may be used as etch stop layers when the dummy gates 76 are etched. The dummy dielectric layers 60 may then be removed after the removal of the dummy gates 76.

In FIGS. 16A-16H, the first nanostructures 52 are removed from the n-type region 50N and the p-type region 50P extending the second recesses 98. FIG. 16A and B illustrates removing the first nanostructures 52 by performing an isotropic etching process such as wet etching or the like. In some embodiments, removing the first nanostructures 52 may include using etchants that are selective to removing the materials of the first nanostructures 52, while the second nanostructures 54, the substrate 50, the STI regions 68 remain relatively unetched. The first nanostructures 52 may be removed from the first stacks in the n-type region 50N and the p-type region 50P simultaneously without requiring blocks masks and/or masking for separating the processing applied to the n-type region 50N and the p-type region 50P for the purposes of removing the first nanostructures 52.

FIG. 16C illustrates an embodiment of how the first mixed composition interface layer 57 and the second mixed composition interface layer 58 may be employed an etch stop for removing the first nanostructures 52. In FIG. 16C, a stack including the first mixed composition interface layer 57 is identified by reference number 50N′, which illustrates that the stack depicted in FIG. 16C is consistent with the stacks having the first intermixed composition interface layers 57 that are present in the n-type region 50N that is depicted in FIGS. 16A, 16B and 16D. In FIG. 16D, a stack including the second mixed composition interface layer 58 is identified by reference number 50P′, which illustrates that the stack depicted in FIG. 16C is consistent with the stacks having the second intermixed composition interface layers 58 that are present in the p-type region 50P that is depicted in FIGS. 16A, 16B and 16D.

FIG. 16C illustrates an etch sequence of three stages. The initial stage 300 depicted in FIG. 16C illustrates a stack 50N′ depicted in the n-type region 50N and a stack 50P′ depicted in the p-type region 50P. The portions of the stacks 50N′, 50P′ depicted in FIG. 16C include two second nanostructures 54 having a first nanostructure 52 that is present between the two depicted second nanostructures 54. The stack 50N′ in the n-type region 50N includes first mixed composition interface layers 57 present at the interfaces between the first and second nanostructures 52, 54. The stack 50P′ in the p-type region 50P includes the second mixed composition interface layers 58 present at the interfaces between the first and second nanostructures 52, 54. As noted above, the first and second mixed composition interface layers 57, 58 may be formed from elements diffusing, e.g., thermally diffusing, from at least the source/drain regions 92. In some embodiments, the first mixed composition interface layer 57 is a silicon (Si) containing layer including germanium (Ge) in amounts ranging from 0.1% to 5%, and can further include an n-type dopant, such as phosphorus (P), in amounts ranging from 0.01% to 1%. In some embodiments, the second mixed composition interface layer 58 is a silicon (Si) containing layer including germanium (Ge) in amounts ranging from 0.1% to 5%, and can further include a p-type dopant, such as boron (B), in amounts ranging from 0.01% to 1%.

The first etch stage 310 depicted in FIG. 16C illustrates a removing the first nanostructures 52 from the n-type region 50N and the p-type region 50P. In some embodiments, a first nanostructures 52 composed of silicon germanium (SiGe) including germanium ranging from 15% to 40% may be removed selectively to the aforementioned composition for the first mixed composition interface layer 57 by an etch chemistry including at least one of fluorine (F2) gas, hydrogen fluoride (HF) gas, and nitrogen trifluoride (NF3) gas, in which the etch temperature at low temperature. For example, the etch temperature for removing the first nanostructures 52 selectively to the first composition mixed interface layer 57 having the above compositions, and using the aforementioned etch chemistries, may be 40 °C or less.

In some embodiments, a first nanostructure 52 composed of silicon germanium (SiGe) including germanium ranging from 15% to 40% may be removed selectively to the aforementioned composition for the second mixed composition for the second mixed composition interface layer 58 by an etch chemistry including at least one of fluorine (F2) gas, hydrogen fluoride (HF) gas, and nitrogen trifluoride (NF3) gas, in which the etch temperature at low temperature. For example, the etch temperature for removing the first nanostructures 52 selectively to the second mixed composition interface layer 58 having the above compositions, and using the aforementioned etch chemistries, may be 40 °C or less.

It is noted, that the same etch processes for removing the first nanostructures 52 during the first etch stage 310 can be simultaneously applied to the first and second stacks 50N′, 50P′ of first and second nanostructures 52, 54 in the n-type region 50N and the p-type region 50P without using separate etch masks and/or masking for separately applying etchant to the n-type region 50N and the p-type region 50P. In some embodiments, the etch chemistry for removing the first nanostructures 52 is selective to the first and second mixed composition interface layers 57, 58, the second nanostructures 54, the isolation regions 68, and the substrate 50.

It is noted at the first etch stage 310 of the process sequence depicted in FIG. 16C, the height (also referred to as thickness) of the second nanostructures 54A, 54B, 54C of the stack 50N′ in the n-type region 50N is equal to the height of the second nanostructures 54D, 54E, 54F of the stack 50P′ in the p-type region 50P, as illustrated in FIGS. 16A and 16B. Further, at this stage of the process sequence, the first and second mixed composition interface layers 57, 58 acted as an etch stop, and were not substantially etched by the etch chemistry use for removing the first nanostructures 52. Therefore, the first and second mixed composition interface layers 57, 58 also have substantially that same height (also referred to as thickness) following the first etch stage 310.

Referring to FIGS. 16C-16E, a second etch stage 320 may be applied for trimming the height of the structures including the first nanostructures 55 and the first and second mixed composition interface layers 57, 58. The second etch stage 320 may be referred to as a trimming etch. During the second etch stage, the etch rate for the first mixed composition interface layer 57 is increased by the n-type dopant (e.g., phosphorus (P)) that is present therein, when compared to the etch rate of the second mixed composition interface layer 58 that does not include the n-type dopant. The second mixed composition interface layer 58 is p-type doped, e.g., doped with boron (B). As noted above, the n-type dopant that is present in the first mixed composition interface layer 57, and the p-type dopant that is present in the second mixed composition interface layer 58 are diffused from the source/drain regions 92. The source/drain regions 92 in the n-type region 50N are doped to an n-type dopant, and therefore can introduce the n-type dopant to the stacks 50N′ including the first mixed composition interface layer 57 that are present in the n-type region 50N by diffusion, e.g., thermal diffusion. The source/drain regions 92 in the p-type region 50P are doped to a p-type dopant, and therefore can introduce the p-type dopant to the stacks 50P′ including the second mixed composition interface layer 58 that are present in the p-type region 50P by diffusion, e.g., thermal diffusion.

For example, the first mixed composition interface layer 57 is a silicon containing layer including up to 5% germanium and up to 1% phosphorus (P); and the second mixed composition interface layer 58 is a silicon containing layer including up to 5% germanium and up to 1% boron (B). In some embodiments, the phosphorus (P) increases the etch rate (also referred to as trimming rate) of the first mixed composition interface layer 57. For example, during the second etch stage 320, the etch rate for silicon germanium (SiGe) doped with phosphorus (P) is greater than the etch rate for silicon germanium that is not doped. Further, during the second etch stage 320, the etch rate for undoped silicon germanium (SiGe) is greater than the etch rate of silicon germanium (SiGe) that is doped with boron (B). For example, the etch rate of the second mixed composition interface layer is decreased by the p-type dopants (e.g., boron (B)) that is present therein, when compared to the etch rate of the first mixed composition interface layer 57 that does not include the p-type dopant.

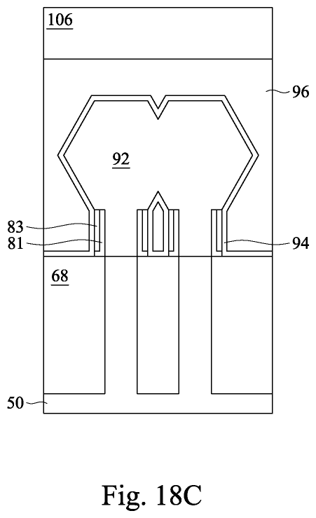

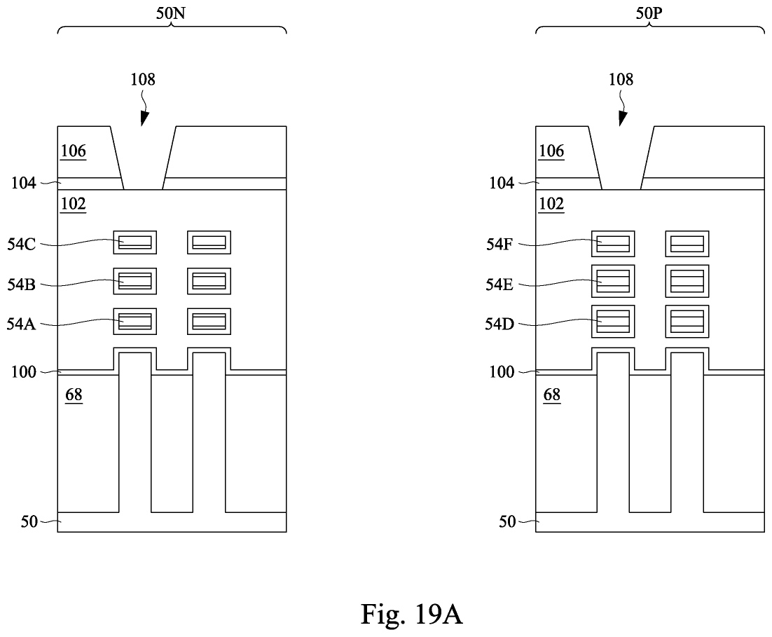

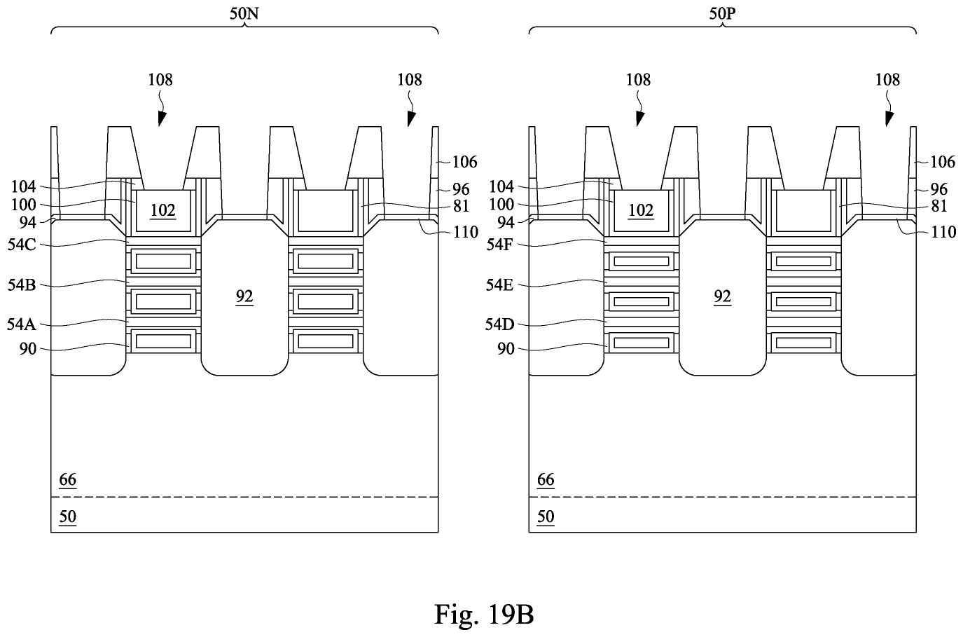

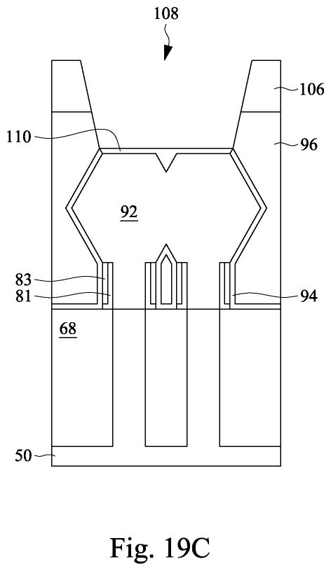

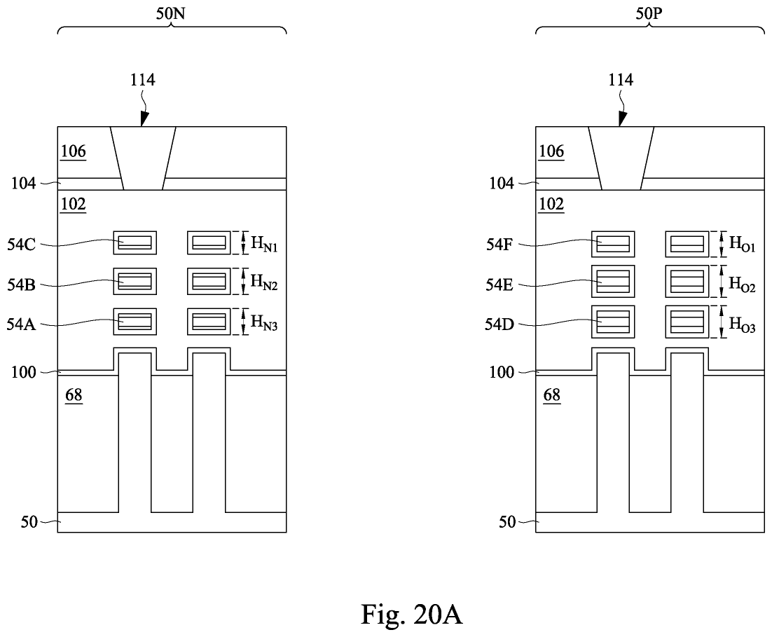

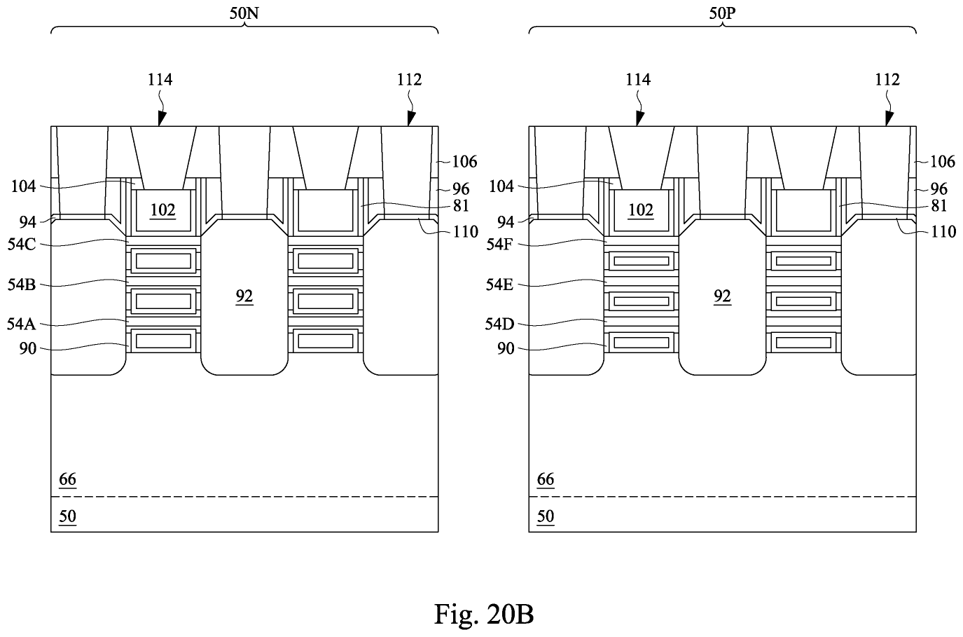

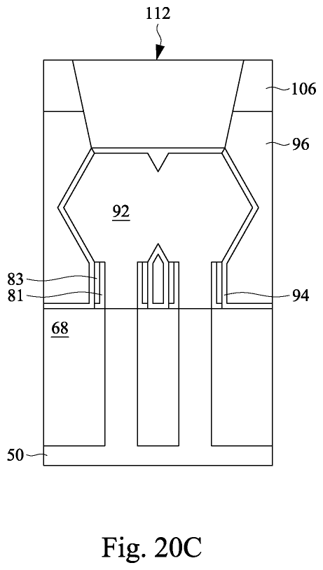

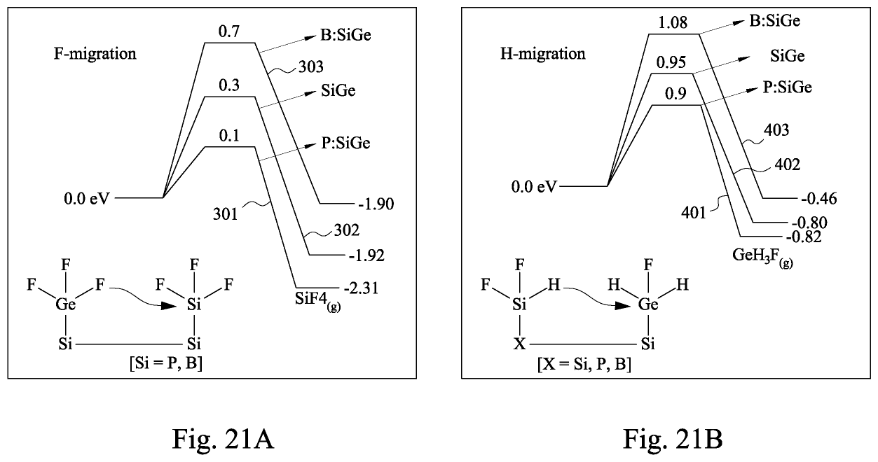

FIGS. 21A and 21B illustrate how the etch rate of silicon germanium with hydrogen and fluorine containing etch gasses is impacted by n-type and p-type dopants, such as phosphorus (P) and boron (B). FIG. 21A is a plot of activation energy for fluorine (fluorine migration) to cause a chemical reaction in silicon germanium, e.g., how easily silicon germanium etches. The activation energy is the energy required by the system to undergo a chemical reaction. Higher activation energy means etching species have less energy and more thermal energy is needed for etching to occur.

The lower the activation energy, the faster the etch rate. Plot line 301 is the activation energy of a silicon germanium (SiGe) material that is doped with phosphorus (P). Plot line 302 is the activation energy of a silicon germanium (SiGe) material that is not doped with an n-type or p-type dopant. Plot line 303 is the activation energy of a silicon germanium (SiGe) material that is doped with boron (B).

The activation energy of silicon germanium (SiGe) doped with phosphorus is lower than the activation energy of silicon germanium (SiGe) that is not doped with n-type or p-type dopants. The etch rate of silicon germanium doped with phosphorus (P) is greater than the etch rate of silicon germanium (SiGe) that is not doped with n-type or p-type dopants for fluorine containing etchants. The activation energy of silicon germanium (SiGe) doped with boron is greater than the activation energy of silicon germanium that is not doped with n-type or p-type dopant. The etch rate of silicon germanium doped with boron (B) is less than the etch rate of silicon germanium that is not doped with n-type or p-type dopants for fluorine containing etchants.

FIG. 21B is a plot of activation energy for hydrogen to cause a chemical reaction in silicon germanium, e.g., how easily silicon germanium etches. Plot line 401 is the activation energy of a silicon germanium (SiGe) material that is doped with phosphorus (P). Plot line 402 is the activation energy of a silicon germanium (SiGe) material that is not doped with an n-type or p-type dopant. Plot line 403 is the activation energy of a silicon germanium (SiGe) material that is doped with boron (B).

The activation energy of silicon germanium (SiGe) doped with phosphorus is lower than the activation energy of silicon germanium (SiGe) that is not doped with n-type or p-type dopants. The etch rate of silicon germanium doped with phosphorus (P) is greater than the etch rate of silicon germanium (SiGe) that is not doped with n-type or p-type dopants for fluorine containing etchants. The activation energy of silicon germanium (SiGe) doped with boron is greater than the activation energy of silicon germanium that is not doped with n-type or p-type dopant. The etch rate of silicon germanium doped with boron (B) is less than the etch rate of silicon germanium that is not doped with n-type or p-type dopants for fluorine containing etchants.

In some embodiments, the second etch stage 320 (trimming etch) etches the first mixed composition interface layer 57 to a greater degree than the second mixed composition interface layer 58. This provides that after the second etch stage 320 (trimming etch) the first mixed composition interface layer 57 has a less height (also referred to as thickness) than the second mixed composition interface layer 58. In some embodiments, the difference in etch rate between the first mixed composition interface layer 57 and the second mixed composition interface layer 58 can result in a difference in the height (also referred to as thickness) between the simultaneously etched first and second mixed composition interface layers 57, 58 that can range from 0.5 nm to 1.5 nm. In an example, the difference in etch rate between the first mixed composition interface layer 57 and the second mixed composition interface layer 58 can result in a difference in the height (also referred to as thickness) between the simultaneously etched first and second mixed composition interface layers 57, 58 that can range from 0.5 nm to 1.o nm.

In some embodiments in which the first mixed composition interface layer 57 is composed of silicon (Si) including up to 5% of germanium (Ge), and up to 1% of phosphorus (P); and the second mixed composition interface layer 58 is composed of silicon (Si) including up to 5% of germanium (Ge) and up to 1% of boron (B). The etch chemistry for the second etch stage 320 can include ammonia (NH3) gas, and the temperature at the second etch stage 320 is applied at a higher temperature than the temperature for the first etch stage 310. For example, the etch chemistry for the second etch stage 320 can include fluorine (F2) gas, hydrogen fluoride (HF) gas, nitrogen trifluoride (NF3) gas, and ammonia (NH3) gas. For example, the etch temperature for trimming the height (also referred to as thickness) for the first mixed composition interface layer 57 selectively to the second mixed composition interface layer 58 may be at an etch temperature that is greater than 40 °C.

It is noted, that the same etch processes for trimming the first mixed composition interface layer 57 during the second etch stage 320 can be simultaneously applied to the first and second stacks 50N′, 50P′ of second nanostructures 54 in the n-type region 50N and the p-type region 50P without using separate etch masks and/or masking for separately applying etchant to the n-type region 50N and the p-type region 50P. In some embodiments, the etch chemistry for trimming the first mixed composition interface layers 57 selectively to the second mixed composition interface layers 58 may also be selective to the second nanostructures 54, the isolation regions 68, and the substrate 50.

FIG. 16F illustrates the height and width dimensions of the stacks of the second nanostructures 54 with the remaining portions of the first and second mixed composition interface layers 57, 58 for each of the n-type region 50N and the p-type region 50P following the second etch stage 320. FIG. 16F illustrates that the differentiated sheet height between the remaining portions of the first mixed composition interface layers 57 and the second nanostructures 54 in the n-type region 50N, and the remaining portions of the second mixed composition interface layers 58 and the nanostructures 54 in the p-type region 50P. FIG. 16F illustrates that the sheet height HN1, HN2, HN3 provided by the first mixed composition interface layers 57 and the second nanostructures 54 in the n-type region 50N is less than the sheet height HP1, HP2, HP3 provided by the second mixed composition interface layers 58 and the second nanostructures 54 in the p-type region 50P. FIG. 16F further illustrates that the sheet width WN1, WN2, WN3 provided by the first mixed composition interface layers 57 and the second nanostructures 54 in the n-type region 50N is equal to the sheet width WP1, WP2, WP3 provided by the second mixed composition interface layers 58 and the second nanostructures 54 in the p-type region 50P.

In one example, the sheet height HN1, HN2, HN3 provided by the first mixed composition interface layers 57 and the second nanostructures 54 in the n-type region 50N may range from 3 nm to 8 nm. In one example, the sheet height HP1, HP2, HP3 provided by the second mixed composition interface layers 58 and the second nanostructures 54 in the p-type region 50P may range from 3 nm to 8 nm. However, there is a differential in the sheet height that results from the differential etch process described above for simultaneously etching the first mixed composition interface layer 57 and the second mixed composition interface layer 58 may range from 0.3 nm to 1 nm. For example, when the differential in sheet height is 1 nm, and the sheet height HN1, HN2, HN3 for the first mixed composition interface layers 57 and the second nanostructures 54 in the n-type region 50N is equal to 4 nm, the sheet height HP1, HP2, HP3 provided by the second mixed composition interface layers 58 and the second nanostructures 54 in the p-type region 50P is equal to about 5 nm. In some embodiments, the sheet width WN1, WN2, WN3 provided by the first mixed composition interface layers 57 and the second nanostructures 54 in the n-type region 50N is substantially equal (e.g., within +/−0.2 nm or less) to the sheet width WP1, WP2, WP3 provided by the second mixed composition interface layers 58 and the second nanostructures 54 in the p-type region 50P.

FIG. 16F further illustrates the vertical spacing dimensions SN1, SN2, SN3 separating the adjacently stacked structures of second nanostructures 54 and first mixed composition interface layers 57 in the n-type region 50N, and the vertical spacing dimensions SP1, SP2, SP3 separating the adjacently stacked structures of the second nanostructures 54 and the second mixed composition interface layers 58 in the p-type region 50P following the second etch stage 320. By allowing for the vertical spacing to be independently controlled in the n-type region 50N and the p-type region 50P, the methods and structures described herein can provide tunable NFET and PFET performance. In some embodiments, by providing tunable NFET and PFET performance through differentiated vertical spacing for the semiconductor layers, e.g., nanosheets, the methods and structures described herein can result in better wafer acceptance testing (WAT) performance.

FIG. 16F illustrates that the vertical spacing dimensions SN1, SN2, SN3 separating the adjacently stacked structures of second nanostructures 54 and first mixed composition interface layers 57 in the n-type region 50N are greater than the vertical spacing dimensions SP1, SP2, SP3 separating the adjacently stacked structures of the second nanostructures 54 and the second mixed composition interface layers 58 in the p-type region 50P. For example, the vertical spacing dimensions SN1, SN2, SN3 separating the adjacently stacked structures of second nanostructures 54 and the first mixed composition interface layers 57 in the n-type region 50N may range from 3 nm to 8 nm. For example, the vertical spacing dimensions SP1, SP2, SP3 separating the adjacently stacked structures of second nanostructures 54 and the first mixed composition interface layers 57 in the p-type region 50P may range from 3 nm to 8 nm. However, there is a differential in the vertical spacing dimensions that results from the differential etch process described above for simultaneously etching the first mixed composition interface layer 57 and the second mixed composition interface layer 58. In some embodiments, the differential in the vertical spacing dimensions may range from 0.3 nm to 1 nm. For example, when the differential in vertical spacing dimensions is 1 nm, and the vertical spacing dimensions SN1, SN2, SN3 separating the adjacently stacked structures of second nanostructures 54 and the first mixed composition interface layers 57 in the n-type region 50N is equal to 4 nm, the vertical spacing dimensions SP1, SP2, SP3 separating the adjacently stacked structures of second nanostructures 54 and the first mixed composition interface layers 57 in the p-type region 50P may be equal to 3 nm.

Referring to FIG. 16E, although there is a differential between the vertical spacing between the nanostructures in the P-type region 50P and the n-type region 50N, the critical dimension CDN1, CDN2, CDN3 (channel length) for the second nanostructures 54 in the n-type region 50N is the same as the critical dimension CDP1, CDP2, CDP3 (channel length) for the second nanostructures 54 in the p-type region 50P. For example, the critical dimension CDN1, CDN2, CDN3 (channel length) for the second nanostructures 54 in the n-type region 50N may range from 10 nm to 20 nm, and the critical dimension CDP1, CDP2, CDP3 (channel length) for the second nanostructures 54 in the p-type region 50P may range from 10 nm to 20 nm.

FIG. 16E also illustrates that the channel regions provided by the second nanostructures 54 and the trimmed first and second mixed composition interface layers 57, 58 for each of the n-type region 5oN and the p-type region 50P. During the above described trimming step, a portion of the first and second mixed composition interface layers 57, 58 is overlapped by the first inner spacers 90. The portion of the first and second mixed composition interface layers 57, 58 that are in contacted (overlapped) by the first inner spacers 90 are protected from the etch for trimming the height of the channels. The protected portions of the first and second mixed composition interface layers 57, 58 maintain their original height following the above described etch processes. The original height of the first and second mixed composition interface layers 57, 58 at the ends of the channel regions with a thinned central portion of the first and second mixed composition interface layers 57, 58 produce a side cross-sectional for the channel regions having an H-type geometry.

FIG. 16G illustrates the total height for the stacks 50N′, 50P′ of the second nanostructures 54 with the remaining portions of the first and second mixed composition interface layers 57, 58 for each of the n-type region 50N and the p-type region 50P following the second etch stage 320. The total height TN1 of the stack in the n-type region is equal to the total height TP1 of the stack in the p-type region. The total height TN1, TP1 is the dimension from the upper surface of the isolation region 68 to the upper surface to the second nanostructure 55 that provides the top sheet of the stacks. In one example, the total height TN1 for the stack in the n-type region 50N may range from 40 nm t0 60 nm, and the total height TP1 for the stack in the p-type region 50P may range from 40 nm to 60 nm.

In the embodiment depicted in FIG. 16G, each stack 50N′, 50P′ includes three vertically stacked second nanostructures 54. In some embodiments, although the total height TP1, TP2 to the top sheet is the same for each of the stacks 50N′, 50P′ in the n-type region 50N and the p-type region 50P, the height for the middle and lower second nanostructures 54 from the isolation region 68 in the n-type region 50N is less than the height for the middle and lower second nanostructures 54 from the isolation region 68 in the p-type region 50P.

The total height TN2, TP2 of the middle second nanostructures 54 is measured from the upper surface of the isolation region 68. In one example, the total height TN2 of the middle second nanostructure 54 in the n-type region 50N ranges from 25 nm to 40 nm. In one example, the total height TP2 of the middle second nanostructure 54 in the p-type region 50P ranges from 25 nm to 40 nm. However, the differential between the total height TN2 for the middle second nanostructure 54 in the n-type region 50N and the total height TP2 for the middle second nanostructure 54 in the p-type region 50P may range from 0.3 nm to 0.5 nm.

The total height TN3, TP3 of the lower second nanostructures is also measured from the upper surface of the isolation region. In one example, the total height TN3 of the lower second nanostructure 54 in the n-type region 50N ranges from 10 nm to 20 nm. In one example, the total height TP3 of the lower second nanostructure 54 in the p-type region 50P ranges from 10 nm to 20 nm. However, the differential between the total height TN1 for the lower second nanostructure 54 in the n-type region 50N and the total height TP1 for the lower second nanostructure 54 in the p-type region 50P may range from 0.3 nm to 0.5 nm.

FIG. 16H illustrates one embodiment of sheet end rounding that occurs at the edges of the second nanostructures 54 during the etching processes for removing the first nanostructures 52 and trimming the first mixed composition interface layer 57. As illustrated in FIG. 16H, the second nanostructures 54 for the stacks 50N′ in the n-type region 50N have a more rounded corner than the second nanostructures 54 in the stacks 50P′ in the p-type region 50P. As illustrated in FIG. 16H, the second nanostructures 54 in the p-type region 50P have a more square corner than the second nanostructures 55 in the n-type region 50N. For the second nanostructures 54 in the n-type region 50N, the corners may be trimmed by a dimension RN1T, RN1B up to 2 nm, as measured from the original corner. For the second nanostructures in the p-type region 50P, the corners may be trimmed by a dimension Rp1T, Rp1B up to 1 nm, as measured from the original corner.

It is noted that the embodiments depicted in FIGS. 16A-16H is provided for illustrative purposes only, and it is not intended to limit the present disclosure to only the examples depicted in FIGS. 16A-16H. For example, the stacks depicted in FIGS. 16A-16H only includes three nanostructures. The present disclosure is not limited to only this number of nanostructures in the stacks.

In FIGS. 17A and 17B, gate dielectric layers 100 and gate electrodes 102 are formed for replacement gates. The gate dielectric layers 100 are deposited conformally in the second recesses 98. In the n-type region 50N, the gate dielectric layers 100 may be formed on top surfaces and sidewalls of the substrate 50 and on top surfaces, sidewalls, and bottom surfaces of the second nanostructures 54A, 54B, 54C, and in the p-type region 50P, the gate dielectric layers 100 may be formed on top surfaces and sidewalls of the substrate 50 and on top surfaces, sidewalls, and bottom surfaces of the second nanostructures 54E, 54C, 54D. The gate dielectric layers 100 may also be deposited on top surfaces of the first ILD 96, the CESL 94, the first spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectric layers 100 may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17B, the gate electrodes 102 may comprise any number of liner layers, any number of work function tuning layers, and a fill material. Any combination of the layers which make up the gate electrodes 102 may be deposited in the n-type region 50N between adjacent ones of the second nanostructures 54B, 54C and between the second nanostructure 54A and the substrate 50, and may be deposited in the p-type region 50P between adjacent ones of the second nanostructures 54E, 54F and between the second nanostructure 54D and the substrate 50.

The formation of the gate dielectric layers 100 in the n-type region 50N and the p-type region 50P may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

In FIGS. 18A-18C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 114, discussed below with respect to FIGS. 20A-20C) penetrate through the gate mask 104 to contact the top surface of the recessed gate electrodes 102.

As further illustrated by FIGS. 18A-18C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

In FIGS. 19A-19C, the second ILD 106, the first ILD 96, the CESL 94, and the gate masks 104 are etched to form third recesses 108 exposing surfaces of the epitaxial source/drain regions 92 and/or the gate structure. The third recesses 108 may be formed by etching using an anisotropic etching process, such as RIE, NBE, or the like. In some embodiments, the third recesses 108 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 108 extend into the epitaxial source/drain regions 92 and/or the gate structure, and a bottom of the third recesses 108 may be level with (e.g., at a same level, or having a same distance from the substrate), or lower than (e.g., closer to the substrate) the epitaxial source/drain regions 92 and/or the gate structure. Although FIG. 19B illustrate the third recesses 108 as exposing the epitaxial source/drain regions 92 and the gate structure in a same cross section, in various embodiments, the epitaxial source/drain regions 92 and the gate structure may be exposed in different cross-sections, thereby reducing the risk of shorting subsequently formed contacts. After the third recesses 108 are formed, silicide regions 110 are formed over the epitaxial source/drain regions 92. In some embodiments, the silicide regions 110 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 110. The un-reacted portions of the deposited metal are then removed, e.g., by an etching process. Although silicide regions 110 are referred to as silicide regions, silicide regions 110 may also be germanide regions, or silicon germanide regions (e.g., regions comprising silicide and germanide). In an embodiment, the silicide region 110 comprises TiSi, and has a thickness in a range between about 2 nm and about 10 nm.

Next, in FIGS. 20A-C, contacts 112 and 114 (may also be referred to as contact plugs) are formed in the third recesses 108. The contacts 112 and 114 may each comprise one or more layers, such as barrier layers, diffusion layers, and fill materials. For example, in some embodiments, the contacts 112 and 114 each include a barrier layer and a conductive material, and is electrically coupled to the underlying conductive feature (e.g., gate electrode 102 and/or silicide region 110 in the illustrated embodiment). The contacts 114 are electrically coupled to the gate electrode 102 and may be referred to as gate contacts, and the contacts 112 are electrically coupled to the silicide regions 110 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

FIGS. 20A-20C illustrate a semiconductor device that includes a substrate 50 including a first device region, e.g., n-type region 50N, and a second device region, e.g., p-type region 50P. In some embodiments, a first type device, e.g., n-type device, is present in the first device region. In some embodiments, the first type device includes a first stack of nanostructures and a first gate stack 102, 100 around each first nanostructure of the first stack of nanostructures. The first nanostructures may be provided by the second nanostructures 54A, 54B, 54C that are present in the n-type region 50N. In some embodiments, each first nanostructure of the first stack of nanostructures has a first height HN1, HN2, HN3. In some embodiments, the second device type, e.g., p-type device, in the second device region, e.g., p-type region 50P, includes a second stack of nanostructures, and a second gate stack 102, 100 around each second nanostructure 54 of the second stack of nanostructures. The second stack of nanostructures is provided by the second nanostructures 54D, 54E, 54F that are present in the p-type region 50P. In some embodiments, each second nanostructure of the second stack of nanostructures has a second height HP1, HP2, HP3. The second height HP1, HP2, HP3 is different than the first height HN1, HN2, HN3. For example, the second height HP1, HP2, HP3 can be greater than the first height HN1, HN2, HN3. In some embodiments, the first spacing SN1, SN2, SN3 between adjacently stacked nanostructures in the first stack of nanostructures 54a, 54b, 54c is greater than second spacing SP1, SP2, SP3 between adjacently stacked nanostructures 54d, 54e, 54f in the second stack of nanostructures. In some embodiments, each first nanostructure (provided by second nanostructures having reference numbers 54A, 54B, 54C) in the first stack of nanostructures has a first width WN1, WN2, WN3, and the each second nanostructure (provided by second nanostructures 54D, 54E, 54F) in the second stack of nanostructures has a second width WP1, WP2, WP3, the first width equal to the second width.

The difference in the dimensions for the nanostructures in the p-type region 50P and the n-type region 50N may be provided by first and second mixed composition interface layers 57, 58 that have different etch rates. As described above, the n-type dopant that is present in the first mixed composition interface layers 57 increases the etch rate of the first mixed composition interface layer 57 relative to the second mixed composition interface layer 58 that does not include the n-type dopant. In some embodiments, the second nanostructures 54a, 54b, 54c, 54d, 54e, 54f may be referred to as the core material of nanostructure, and the first and second mixed composition interface layers 57, 58 may be referred to as surface layers that are present on the core components of the nanostructures.

Embodiments may achieve advantages. For example, the methods and structures described herein can provide a simple process for providing nanosheet stacks having different nanosheet heights. More particularly, stacks of nanosheets having different nanosheet heights may be simultaneously formed using a single step etch with no extra patterning processes to separately process a single stack of nanosheets for the purposes of providing different nanosheet heights. The methods and structures provided herein can provide a tunable sheet height within separate stacks of nanosheets. The methods and structures provided herein may provide a larger process window for wafer acceptance testing (WAT) control.

In an embodiment, a semiconductor device has been described that includes a substrate including a first device region and a second device region; a first type device in the first device region, the first type device including a first stack of nanostructures, and a first gate stack around each first nanostructure of the first stack of nanostructures, wherein said each first nanostructure of the first stack of nanostructures has a first height; and a second type device in the second device region, the second type device including a second stack of nanostructures, and a second gate stack around each second nanostructure of the second stack of nanostructures, wherein said each second nanostructure of the second stack of nanostructures has a second height, the second height being different than the first height. In an embodiment, the first type device includes first source/drain regions at opposing ends of each first nanostructure having an n-type conductivity, and the second type device includes second source/drain regions. In an embodiment, the second height is greater than the first height. In an embodiment, first spacing between adjacently stacked nanostructures in the first stack of nanostructures is greater than second spacing between adjacently stacked nanostructures in the second stack of nanostructures. In an embodiment, each first nanostructure in the first stack of nanostructures has a first width, and each second nanostructure in the second stack of nanostructures has a second width, the first width equal to the second width. In an embodiment, a first total height for the first stack of nanostructures is equal to a second total height for the second stack of nanostructures. In an embodiment, a first curvature of a first sidewall for the each first nanostructure in the first stack of nanostructures is greater than a second curvature of a second sidewalls for the each second nanostructure in the second stack of nanostructures.

In an embodiment, a semiconductor device including a substrate including a first device region and a second device region. A first conductivity type device is present in the first device region. The first conductivity type device including a first stack of nanostructures, and a first gate stack around each first nanostructure of the first stack of nanostructures, wherein said each first nanostructure of the first stack of nanostructures includes a first core of a first semiconductor element, and a first surface layer of a first conductivity type dopant, a second semiconductor element and the first semiconductor element. The first stack has a first total height, and the first core and the first surface layer has a first combined thickness. The semiconductor device further includes a second conductivity type device in the second device region. The second conductivity type device includes a second stack of nanostructures, and a second gate stack around each second nanostructure of the second stack of nanostructures. Each second nanostructure of the second stack of nanostructures includes a second core of the first semiconductor element, and a second surface layer of a second conductivity type dopant, the second semiconductor element and the first semiconductor element. The second stack has a second total height, and the second core and the second surface layer has a second combined thickness, wherein the first total height is equal to the second total height and the second combined thickness is different than the first combined thickness. In an embodiment, the first conductivity type device includes first source/drain regions at opposing ends of each first nanostructure having an n-type conductivity, and the second conductivity type device includes second source/drain regions having a p-type conductivity. In an embodiment, the first semiconductor element comprises silicon, and the second semiconductor element comprises germanium. In an embodiment, the second combined thickness is greater than the first combined thickness, and the first core has a thickness equal to the second core. In an embodiment, the first spacing between adjacently stacked nanostructures in the first stack of nanostructures is equal to second spacing between adjacently stacked nanostructures in the second stack of nanostructures, wherein the each first nanostructure in the first stack of nanostructures has a first width, and the each second nanostructure in the second stack of nanostructures has a second width, the first width equal to the second width. In an embodiment, the first conductivity type dopant is an n-type dopant, and the second conductivity type dopant is a p-type dopant. In an embodiment, the n-type dopant is phosphorus, and the p-type dopant is boron.

In another embodiment, a method of forming a semiconductor device includes forming a first stack of first semiconductor layers and second semiconductor layers in a first region of a substrate, and a second stack of the first semiconductor layers and the second semiconductor layers in a second region of the substrate, the second semiconductor layer of the first stack of including a first conductivity type dopant and the second semiconductor layer of the second stack including a second conductivity type dopant, wherein a mixed composition interface layer is present between the first and second semiconductor layers in each of the first and second stack; removing the first semiconductor layers with an etch that is selective to at least the mixed composition interface layer for each of the first stack and the second stack; etching the mixed composition interlayer for the first stack and second stack, wherein the first conductivity dopant in the mixed composition interface layer within the first stack increases the etch rate of the mixed composition interlayer for the first stack in comparison to the mixed composition interface for the second stack; and forming a gate stack on each of the first stack and the second stack.

In an embodiment, a first remaining portion of the mixed composition interface layer and the second semiconductor layer in the first stack provide a first height, and a second remaining portion of the mixed composition interface layer and the second semiconductor layer in the second stack provide a second height, wherein the second height is greater than the first height. In an embodiment, the first remaining portion of the mixed composition interface layer has a height that is less than the second remaining portion of the mixed composition interface layer, and the second semiconductor layer in the first stack has a height that is equal to the second semiconductor layer in the second stack. In an embodiment, the first conductivity type dopant is an n-type dopant in a silicon containing material of the second semiconductor layer in the first stack, and the second conductivity type dopant is a p-type dopant in the silicon containing material of the second semiconductor layer in the second stack. In an embodiment, the mixed composition interface layer in the first stack includes the first conductivity type dopant, up to 5% germanium and a majority of silicon, and the mixed composition interface layer in the second stack includes the second conductivity type dopant, up to 5% germanium and a majority of silicon. In an embodiment of the method, removing the first semiconductor layers selectively to at least the mixed composition interface layer for each of the first stack and the second stack comprises an etch chemistry selected from the group consisting of F2, HF, NF3 and combinations thereof, wherein an etch temperature is less than 40 °C. In an embodiment of the method, etching of the mixed composition interlayer for the first stack and second stack comprises an etch chemistry including ammonia (NH3), wherein an etch temperature is greater than 40 °C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first stack of nanostructures and a second stack of nanostructures over a substrate, wherein the first stack of nanostructures comprises first semiconductor features that are alternatingly stacked with a first sacrificial material, wherein the second stack of nanostructures comprises second semiconductor features that are alternatingly stacked with a second sacrificial material, wherein the first semiconductor features comprise first nanostructures and first intermix regions, and the second semiconductor features comprise second nanostructures and second intermix regions;
forming first source/drain regions adjoining ends of the first stack of nanostructures, wherein the first source/drain regions are n-type;
forming second source/drain regions adjoining ends of the second stack of nanostructures, wherein the second source/drain regions are p-type;
removing the first sacrificial material from between the first nanostructures and the second sacrificial material from between the second nanostructures;
performing a trimming process that etches first intermix regions at a greater rate than the second intermix regions; and
forming a first gate structure around the first nanostructures and a second gate structure around the second nanostructures.

2. The method of claim 1, wherein after the trimming process, a first height of at least one of the first semiconductor features is less than a second height of at least one of the second semiconductor features.

3. The method of claim 1, wherein after the trimming process, a first distance between adjacent ones of the first semiconductor features is greater than a second distance between adjacent ones of the second semiconductor features.

4. The method of claim 1, wherein the first intermix regions are doped with n-type dopants, and wherein the second intermix regions are doped with p-type dopants.

5. The method of claim 1, wherein removing the first sacrificial material and the second sacrificial material comprises an etching process that is performed at a lower temperature than the trimming process.

6. The method of claim 1, wherein the trimming process rounds first corners of the first semiconductor features to a different degree of curvature than second corners of the second semiconductor features.

7. The method of claim 6, wherein the trimming process rounds the first corners to a greater degree than the second corners.

8. A method comprising:
forming a first stack of nanostructures over a substrate, wherein the first stack of nanostructures comprises:
first nanostructures that are alternatingly stacked with a first sacrificial material; and
first intermix regions between the first nanostructures and the first sacrificial material;
forming first source/drain regions adjoining ends of the first stack of nanostructures, wherein the first source/drain regions comprise n-type dopants;
diffusing the n-type dopants into the first intermix regions;
performing a first etching process that removes the first sacrificial material from between the first nanostructures;
performing a second etching process that trims the first intermix regions, wherein the second etching process is performed at a higher temperature than the first etching process; and
forming a first gate structure around the first nanostructures.

9. The method of claim 8, wherein the first etching process is performed at a temperature greater than 40 °C, and wherein the second etching process is performed at a temperature less than 40 °C.

10. The method of claim 8, wherein the first etching process comprises using a fluorine-comprising etchant, and wherein the second etching process comprises using a hydrogen-comprising etchant.

11. The method of claim 10, wherein the fluorine-comprising etchant comprises F₂, HF, NF₃ or combinations thereof.

12. The method of claim 10, wherein the hydrogen-comprising etchant comprises ammonia (NH₃).

13. The method of claim 8, wherein the first nanostructures comprise silicon, wherein the first sacrificial material comprises silicon germanium, wherein the first intermix regions comprise silicon germanium, and wherein a germanium concentration of the first intermix regions is less than a germanium concentration of the first sacrificial material.

14. The method of claim 13, wherein the germanium concentration of the first sacrificial material is in a range of 15% to 40%, and wherein the germanium concentration of the first intermix regions is in a range of 1% to 5%.

15. The method of claim 8, wherein diffusing the n-type dopants into the first intermix regions comprises a thermal anneal process.

16. The method of claim 8, wherein after diffusing the n-type dopants into the first intermix regions, an n-type dopant concentration in the first intermix regions is in a range of 0.01% to 1%.

17. A method comprising:
forming a first stack of nanostructures and a second stack of nanostructures over a substrate, wherein the first stack of nanostructures comprises first semiconductor features that are alternatingly stacked with a first sacrificial material, wherein the second stack of nanostructures comprises second semiconductor features that are alternatingly stacked with a second sacrificial material, wherein the first semiconductor features comprise first nanostructures and first intermix regions, and the second semiconductor features comprise second nanostructures and second intermix regions;
forming first source/drain regions adjoining ends of the first stack of nanostructures;
forming second source/drain regions adjoining ends of the second stack of nanostructures;
diffusing first dopants from the first source/drain regions into the first intermix regions and second dopants from the second source/drain regions into the second intermix regions, wherein the first dopants have an opposite conductivity type than the second dopants;
performing a first etching process that concurrently removes the first sacrificial material from between the first nanostructures and the second sacrificial material from between the second nanostructures;
performing a second etching process that concurrently trims the first intermix regions and the second intermix regions, wherein after the second etching process, a first height of one or more of the first semiconductor features is less than a second height of one or more of the second semiconductor features; and
forming a first gate structure around the first nanostructures and a second gate structure around the second nanostructures.

18. The method of claim 17, wherein the second etching process is performed at a higher temperature than the first etching process.

19. The method of claim 17, wherein a first etchant of the first etching process comprises fluorine, and wherein a second etchant of the second etching process comprises hydrogen.

20. The method of claim 17, wherein the first dopants are n-type dopants, and the second dopants are p-type dopants.
